(19) United States
(12) Patent Application Publication
(10) Pub. No.: US 2026/0062280 A1
(43) Pub. Date: Mar. 5, 2026

(54) NON-CONTACT MICROELECTROMECHANICAL SYSTEMS

(71) Applicant: TEXAS INSTRUMENTS INCORPORATED, Dallas, TX (US)

(72) Inventors: William Craig McDONALD, Allen, TX (US); Jacky Dale GRIMMETT, Prosper, TX (US); Nathaniel B. GILLY, Dallas, TX (US)

(21) Appl. No.: 18/817,013

(22) Filed: Aug. 27, 2024

(51) Int. Cl. B81B 3/00

(52) U.S. Cl. CPC B81B 3/001; B81B 2201/042; B81B 2203/0181; B81B 2203/04; B81B 2203/058

(57) ABSTRACT

A microelectromechanical systems (MEMS) device includes a mirror, and a mirror post having a first end and a second end, the first end coupled to the mirror. Additionally, the MEMS device includes a hinge having a first side and a second side, the first side of the hinge coupled to the second end of the mirror post. Further, the MEMS device includes a pendulum electrode coupled to the second side of the hinge, and a pair of control electrodes spaced from the pendulum electrode.

### BACKGROUND

This disclosure relates generally to microelectromechanical systems (MEMS) devices such as digital micromirror devices (DMDs). DMDs are MEMS devices that can be used as reflective spatial light modulators. Example DMDs can use amplitude or phase modulation to project light or to project images. Projectors, displays, head up displays, virtual reality and augmented reality vision systems, printers, 3D printers, spectrometers, ranging devices, machine vision, cameras, light sensors and light sources such as automotive headlights or other vehicle headlamps are example applications that can use DMDs. Optical networking systems and light switches can be implemented using DMDs. Visible light including monochrome or colored light can be used with DMDs, and other light including infrared and ultraviolet light can be used with DMDs.

### SUMMARY

In accordance with at least one example of the disclosure, a MEMS device includes a mirror, and a mirror post having a first end and a second end, the first end coupled to the mirror. Additionally, the MEMS device includes a hinge having a first side and a second side, the first side of the hinge coupled to the second end of the mirror post. Further, the MEMS device includes a pendulum electrode coupled to the second side of the hinge, and a pair of control electrodes spaced from the pendulum electrode.

In accordance with at least one example of the disclosure, a MEMS device includes a mirror, and a mirror post having a first end and a second end, the first end coupled to the mirror. Additionally, the MEMS device includes a hinge having a first side and a second side, the first side of the hinge coupled to the mirror post, and a pendulum electrode coupled to the second side of the hinge. Further, the MEMS device includes a pair of control electrodes configured to selectably apply an electrostatic force between electrodes of the pair of control electrodes and the pendulum electrode to thereby rotate the mirror.

In accordance with at least one example of the disclosure, an optical system includes a light source configured to generate a light beam, and a MEMS device optically coupled to the light source. The MEMS device includes a mirror configured to reflect the light beam, and a mirror post having a first end and a second end, the first end coupled to the mirror. Additionally, the MEMS device of the optical system includes a hinge having a first side and a second side, the first side of the hinge coupled to the second end of the mirror post. Further, the MEMS device of the optical system includes a pendulum electrode coupled to the second side of the hinge, and a pair of control electrodes spaced from the pendulum electrode.

### BRIEF DESCRIPTION OF THE DRAWINGS

FIG. 1 illustrates in a block diagram a system for projection using a DMD in accordance with various examples;

FIG. 2 illustrates the operation of a mirror in accordance with various examples;

FIG. 3A illustrates in a plan view a portion of a DMD with mirrors in an on state and in an off state;

FIG. 3B illustrates in a cross-sectional view the tilt operations of mirrors in an on state and in an off state in accordance with various examples.

FIG. 4 illustrates, in a plan view, a portion of a DMD with mirrors in an orthogonal arrangement in accordance with various examples.

FIG. 5 illustrates, in a block diagram, a system for use with an arrangement in accordance with various examples.

FIGS. 6-8 illustrate side views of a MEMS device in accordance with various examples.

FIG. 9 is a perspective view of a MEMS device in accordance with various examples.

FIG. 10 is a top view of the MEMS device of FIG. 9.

FIG. 11 is an exploded perspective view of the MEMS device of FIG. 9.

FIG. 12 is a cross-sectional view of the MEMS device of FIG. 9 along lines 12-12 of FIG. 10.

FIGS. 13 and 14 illustrate side views of a MEMS device in accordance with various examples.

FIG. 15 is a perspective view of a MEMS device in accordance with various examples.

FIG. 16 is a top view of the MEMS device of FIG. 15.

FIG. 17 is a cross-sectional view of the MEMS device of FIG. 15 along lines 17-17 of FIG. 16.

FIGS. 18 and 19 are side views of the MEMS device of FIG. 15.

FIGS. 20-23 are partial side views of the MEMS device of FIG. 15.

FIG. 24 is a perspective exploded view of a MEMS device in accordance with various examples.

FIG. 25 is a perspective view of the MEMS device of FIG. 24.

FIG. 26 is a top view of the MEMS device of FIG. 24.

FIG. 27 is a cross-sectional view of the MEMS device of FIG. 24 along lines 27-27 of FIG. 26.

FIGS. 28-30 are side views of the MEMS device of FIG. 15.

FIG. 31 is a graph illustrating tilt position and control voltages of an exemplary MEMS device in accordance with various examples.

FIG. 32 is a graph illustrating tilt position and control voltages of an exemplary MEMS device in accordance with various examples.

FIG. 33 is a perspective view of a MEMS device in accordance with various examples.

FIG. 34 is a top view of the MEMS device of FIG. 33.

FIGS. 35-44 are side cross-sectional views of a method for forming a MEMS device in accordance with various examples.

### DETAILED DESCRIPTION

The term “pixel” is used herein. Pixel is an abbreviation of the term “picture element. ” A pixel is the smallest addressable element used in a digital display. A DMD pixel is a MEMS device defining one element of an array of addressable picture elements that display a pattern on the DMD for modulating light. MEMS devices such as DMDs can be used to implement a spatial light modulator (“SLM”). In a DMD, the pixels are mirrors. In an example, the SLM is a digital micromirror device and the pixels are formed by mirrors which are a few microns wide and are often referred to as micromirrors. The SLM can have thousands or millions of pixels arranged in rows and columns. In amplitude modulating SLMs implemented using DMDs, when the DMDs are illuminated, the pixels can be described as being in an “on state” or in an “off state”. In the arrangements, a pixel in an on state modulates the illumination light to produce on state light that is arranged to be projected as an image. A pixel in an off state modulates light to produce off state light that is directed away from the projection elements. In this manner the SLM produces projected images.

A DMD contains moveable mirrors that can be rapidly positioned according to stored data. In an example DMD device, an array of picture elements (“pixels”), where each pixel is a mirror, are arranged in a two dimensional array. Each mirror has a corresponding memory element, such as a complementary metal oxide semiconductor (CMOS) static random access memory (SRAM) cell. Data corresponding to an image is loaded into the memory cells, and when the mirrors are powered and switched according to the stored data in the memory cells, the mirrors can tilt to one of two positions, with a first position corresponding to an on state, reflecting illumination light to be projected by the system, or to a second position corresponding to an off state, reflecting light away from the projector in the system. A system including the DMD can rapidly switch patterns so that a wide range of intensity and colors can be displayed by loading the DMD array with a variety of patterns, and illuminating the device many times in a frame period. Intensity gradients can be accomplished using pulse width modulation to switch and illuminate the DMD pattern. High resolution and high contrast can be achieved for systems implemented using DMDs.

The mirrors are subject to stiction-an adhesive force that tends to prevent the surface of a mirror from moving from a landing point as a result of contact between the mirror and another component of the DMD such as a spring tip used to limit further travel or rotation of the mirror. In other words, the mirror may tend to “stick” to the spring tip, preventing the mirror from transitioning to a different tilt position. Stiction tends to keep the mirror in a tilted position. If stiction force exceeds the return forces on the mirror, in some situations stuck mirrors can result. When the mirrors are used as spatial light modulators, a stuck mirror can cause visible defects in the projected images. Reductions in mirror dimensions, such as when a manufactured mirror device is reduced in size from a prior size by dimensional scaling, can increase stiction. In this description, a DMD mirror is described as having a “tilt axis. ”

Embodiments of DMDs or MEMS devices are disclosed herein which avoid the issue of stiction by preventing the mirror of the MEMS device from contacting another (e.g., stationary) component of the MEMS device such as a spring tip and the like. Instead, embodiments of MEMS devices disclosed herein include a pendulum electrode that, while coupled with the mirror, is separate and spaced from the mirror for receiving an electrostatic force from a control electrode of the MEMS device whereby a rotational torque is applied to the mirror through the pendulum electrode for rotating the mirror about the tilt axis. In this manner, contact may be avoided between both the mirror and the pendulum electrode coupled therewith as the mirror rotates about the tilt axis such that the mirror cannot suffer from stiction as a result of contact with another component of the MEMS device.

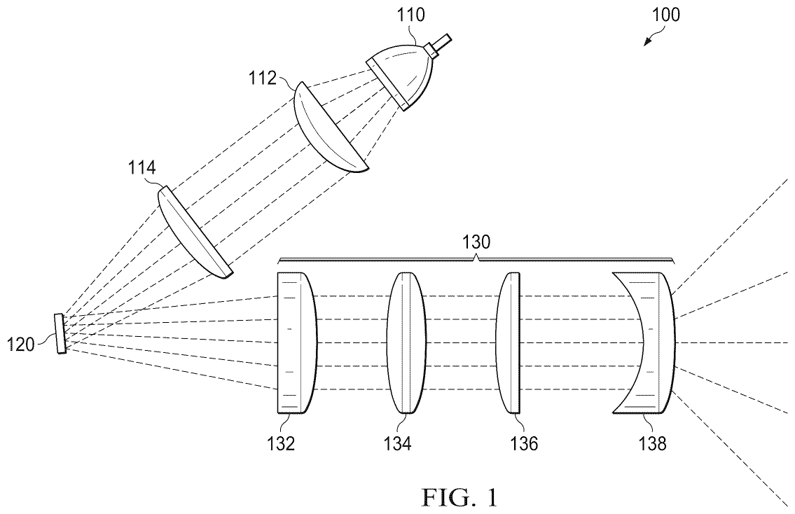

FIG. 1 depicts a block diagram illustrating an example arrangement for a projection system 100. In FIG. 1, a light source 110 produces light, which is transmitted through collection and collimating lens 112. The light beam from the collimating lens 112 travels to a beam shaping lens 114, where the light is focused on the surface of a DMD 120. The light beam is then reflected from mirrors of the DMD 120 to the projection optics 130, which in this example includes a doublet lens 132, a focusing lens 134, a cylindrical lens 136, and an anamorphic lens 138. The arrangements are useful with many applications where DMDs are used, for example digital image projectors including portable projectors, pico-projectors used in smart phones and tablets, video displays, heads up displays, cinema and presentation projectors, video games, light detection and ranging (LIDAR) systems, window displays, smart headlights, and near eye displays, such as virtual reality or augmented reality headsets, glasses, and displays. When color projectors are used, the number of light sources may be increased, for example red, green, and blue light emitting diodes (LEDs) can be used to illuminate the SLM in sequential red-green-blue operations to project color images. Alternative arrangements include using phosphor wheels, color filters, color laser diodes, and/or static phosphors to produce multiple colors.

The light source 110 can produce white light using solid state sources including, for example, LEDs or laser diodes, other white light sources are also useful. Alternatives include using a blue laser to excite a yellow phosphor, a halogen light, or an incandescent light.

After the illuminating light beam is received by the DMD 120, according to image information supplied electronically from an image projection circuit or system, a pattern displayed on the DMD 120 modulates the light. The modulated light is reflected from the DMD 120 and enters the projection lens set 130. Anamorphic lens 138 may also reshape the light beam to meet a desired aspect ratio. In other applications, the anamorphic lens elements may be omitted, and uniform illumination of the DMD 120 and a uniform light distribution in the projected image may be used.

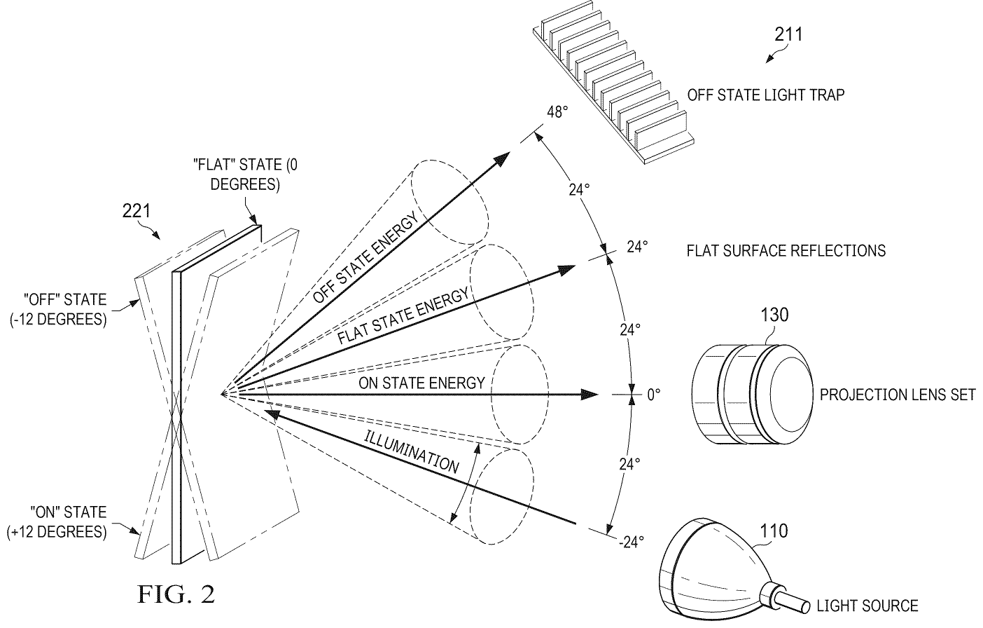

FIG. 2 illustrates the operation of an example mirror 221. A DMD used in the arrangements will have thousands, hundreds of thousands, or even millions of mirrors in a two dimensional array. The example mirror 221 tilts at +/−12 degrees. In DMD devices, varying mirror tilt angles are used such as +/−10 degrees, +/−14 degrees, or +/−17 degrees. When the mirror 221 is not powered, the mirror has a flat state position, which is designated “”FLAT“ STATE (0 DEGREES)” in FIG. 2. When the mirror 221 is in an “OFF” STATE, it tilts away from the flat position to a −12 degree position, and the illumination light received from the light source 110 is reflected to be directed away from the projection lens set 130 and towards a light trap designated OFF STATE LIGHT TRAP 211. When the mirror 221 is in an “ON” STATE, the mirror 221 tilts to a +12 degree position and the illumination light from light source 110 is reflected from the mirror to the projection lens set 130 designated PROJECTION LENS SET. In the FLAT state, the reflected light would be directed to the ray labeled FLAT SURFACE REFLECTIONS, however in a system no illumination is presented to mirrors in the FLAT state so little light would be reflected as FLAT SURFACE REFLECTIONS. As is further described below, in a DMD of the arrangements, an array of memory cells in rows and columns is coupled to the array of mirrors, and the memory cells are written with display data. When the mirrors are updated, the entire array of mirrors changes position in correspondence with the pattern stored in the memory array, the mirrors taking positions determined by the data stored in the associated memory cell. In an arrangement for a device, the memory cells are formed in a silicon substrate in rows and columns, and the mirrors form a mirror array, having rows and columns, over the array of memory cells. The mirrors lie over corresponding memory cells that store data that control the motion of the individual mirrors.

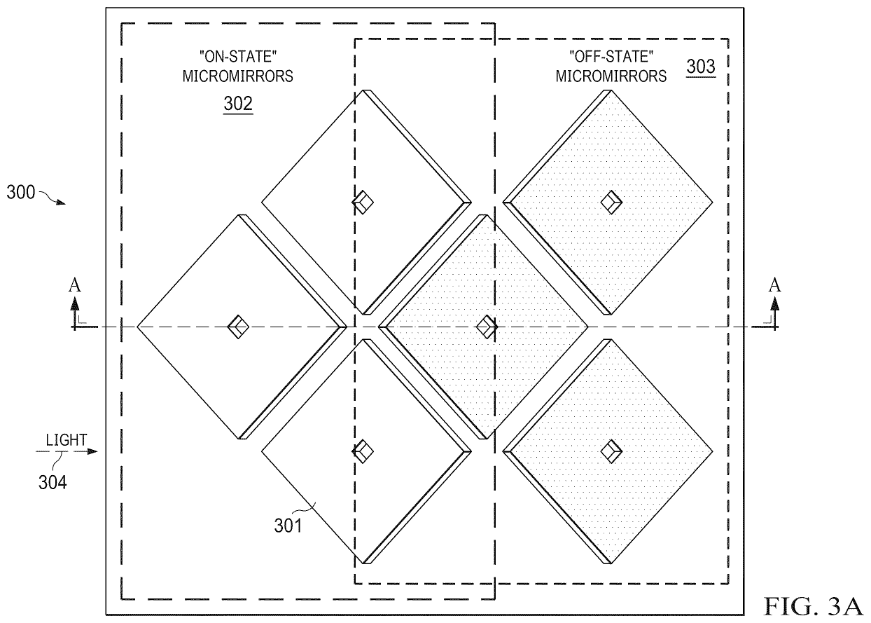

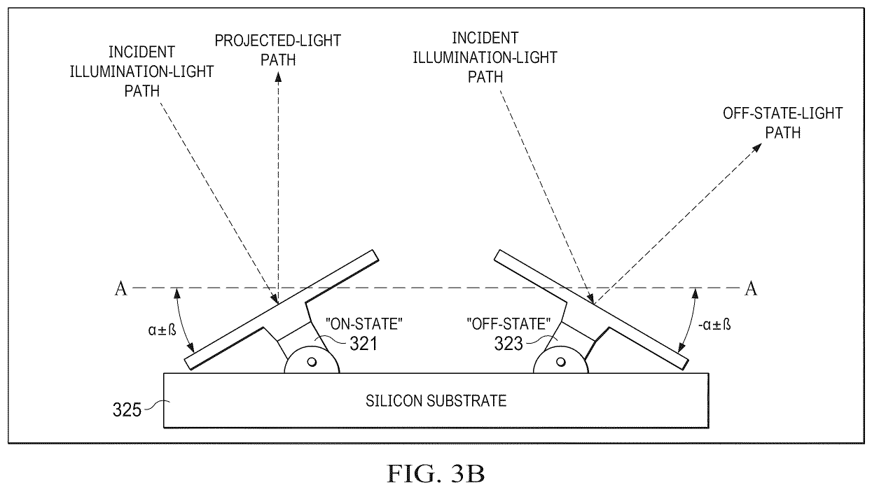

FIGS. 3A and 3B illustrate the operation of a portion 300 of the mirrors 301 in a diamond oriented DMD micromirror array. In FIG. 3A, mirrors 302 are labeled “ON-STATE” MICROMIRRORS and are shown as bright, indicating the light is being projected towards the viewer. Mirrors 303 are labeled “OFF-STATE” MICROMIRRORS“ and are shaded dark, indicating the light is being reflected away from the viewer, and into a light trap (not shown in FIG. 3A). Illumination light 304 labeled “LIGHT” enters the array of mirrors 301 from the left side (as oriented in FIG. 3A).

FIG. 3B shows the operation of an “ON-STATE” mirror and an “OFF-STATE” mirror in a cross sectional view taken along line A-A in FIG. 3A. The mirrors 321 and 323 are shown over a silicon substrate 325. Mirror 321 is in the “ON-STATE”, and is tilted to a positive angle +α with a tolerance +/−β. In the example shown in FIG. 3B, α can be 10 degrees, 12 degrees, 14 degrees, 17 degrees or another angle. Light reflected by the “ON-STATE” mirror 321 is directed towards a path designated the “PROJECTED-LIGHT PATH”. Mirror 323 is in the “OFF-STATE”, and is shown tilted to an angle −α+/−β. The illumination light (designated “INCIDENT ILLUMINATION LIGHT PATH”) is then reflected away from the projection light path to the “OFF-STATE-LIGHT PATH”, and to a light trap (not shown). Using DMDs to modulate the intensity of the incident light is a subtractive process; if all of the mirrors in an array are in the ON state for a given display time, all of the incident illumination light is reflected to a projection light path. For any mirrors in the OFF state, the incident illumination light is reflected away from the projection light path. By loading bit map patterns onto the DMD, the intensity of the light is modulated, and images can be projected. Pulse width modulation of the patterns displayed on the DMD can be used to further vary intensity and to vary color intensity when color illumination is used.

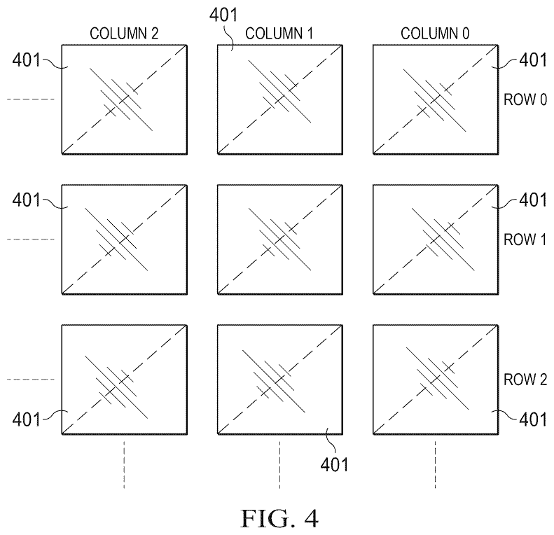

FIG. 4 illustrates, in a top view, a portion of an array of mirrors 401 in an orthogonal arrangement. In FIG. 4, the mirrors 401 tilt about a diagonal mirror tilt axis, and the sides of the mirrors are spaced apart but parallel to one another, with rows and columns of the mirrors aligned. In contrast, in the DMD mirror array shown in FIG. 3A with a diamond pixel orientation, the rows and columns are staggered and the pixels in adjacent rows are interlaced to provide the needed coverage.

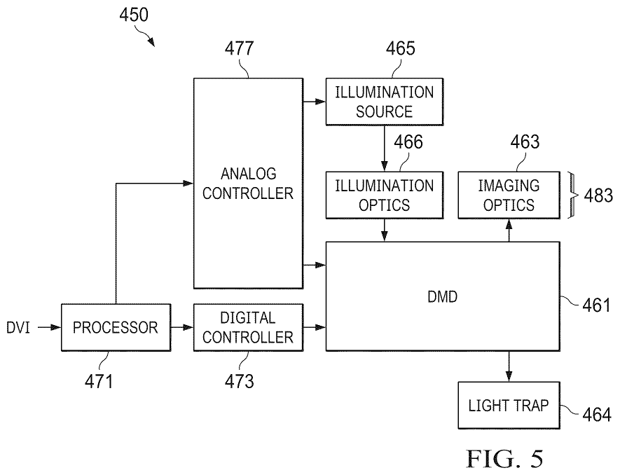

FIG. 5 illustrates, in a block diagram, various elements of a system 450 for use with arrangements. A DMD 461 which includes the pixels of the arrangements without spring tips. Processor 471, which can be implemented using a digital signal processor (DSP), a microprocessor, or a microcontroller unit (MCU), receives digital video input (DVI) signals. A digital controller 473 provides digital data to the DMD 461, including data for display. Analog controller 477 controls power signals to the DMD 461, and to the illumination source 465. Digital controller 473 and analog controllers 477 may comprise single controllers (e.g., a single digital controller 473 and/or a single analog controller 477) in some embodiments while in other embodiments digital controller 473 may comprise a plurality of digital controllers and/or analog controller 477 may comprise a plurality of analog controllers. Light from the illumination source 465 is optically coupled to the DMD 461 by illumination optics 466. On state patterned light from the on state pixels of DMD 461 is then optically coupled to imaging optics 463. The on state patterned light is then projected as on state light 483 and output from the system 450. Off state patterned light reflected from pixels in DMD 461 that are in the off state is optically coupled to a light trap 464.

As DMD technology advances, and for semiconductor devices and MEMS devices generally, devices are increasingly made smaller in size. When fabrication processes advance to support smaller mirrors and circuitry, dimensional scaling may be used to shrink device sizes. Smaller mirror sizes and smaller DMD sizes allow for smaller systems and increased yields on semiconductor wafers as more devices are made on a wafer, reducing costs. Smaller mirrors can also be used to increase resolution by using more pixels per device and by using more pixels per unit area.

When DMD mirrors are reduced in size by dimensional scaling, it has been determined in experiments and by analysis that the forces on the mirror due to stiction, and the opposing electrostatic forces that work to return the mirror to a flat position, do not scale linearly. At some pixel pitch dimensions, existing mirrors have a cross over point at a pixel size where stiction forces exceed the electrostatic forces, and stuck mirrors can be expected. As stuck mirrors are a defect in an SLM, this effect (increasing relative stiction with reduced mirror scaling) restricts the possibility of reducing pixel size. Existing mirror design has one or more spring tips beneath each tilting corner of the mirror, and when tilted, the mirror contacts the spring tip. In embodiments disclosed herein, non-contact MEMS devices are described which do not rely on spring tips and instead entirely avoid physical contact between the mirror and other components (e.g., spring tips) of the MEMS device. In this manner, adhesive forces encountered in other MEMS devices which rely on such physical contact may be avoided.

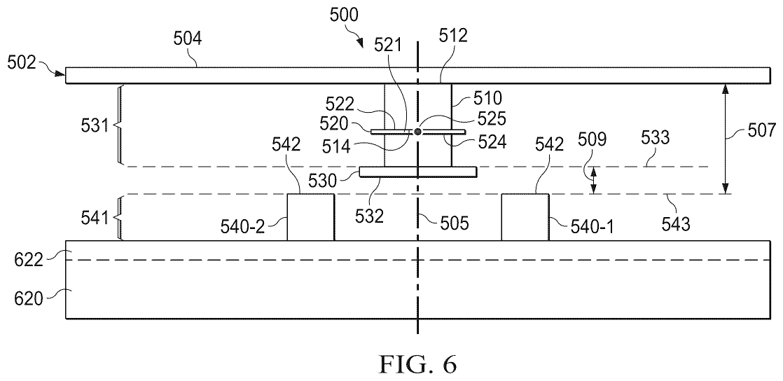

FIGS. 6-8 illustrate schematically a MEMS device 500 in accordance with principles disclosed herein. MEMS device 500 includes a pixel (e.g., a DMD pixel) and thus may also be referred to herein as pixel 500. In this exemplary embodiment, MEMS device 500 includes a mirror 502, a mirror post 510, a hinge 520, a pendulum electrode 530, and a pair of control or address electrodes 540 (shown as control electrodes 540-1 and 540-2 in FIGS. 6-8). In some embodiments, MEMS device 500 additionally includes a semiconductor (e.g., silicon) substrate that physically supports the control electrodes 540 and the hinge 520 and which may include a memory cell electrically coupled to control electrodes 540. The memory cell may include or store data which corresponds to the set of control voltages applied by control electrodes 540. For example, the control electrodes 540 and hinge 520 may be formed or supported on the substrate of MEMS device 500. Additionally, control electrodes 540 are each laterally spaced or offset (e.g., equidistantly) from a longitudinal axis 505 of MEMS device 500.

The mirror 502 of MEMS device 500 has a reflective surface 504 such as, for example, polished aluminum. The mirror post 510 of MEMS device 500 has a first end 512 coupled to the mirror 502, and a second end 514. The hinge 520 of MEMS device 500 defines a central post 521 coupled to mirror post 510 and has a first side 522 and a second side 524. In this exemplary embodiment, the first side 522 of hinge 520 is coupled to the second end 514 of mirror post 510. In addition, hinge 520 has or defines a tilt axis 525 that extends through the hinge 520.

In this exemplary embodiment, mirror 502, mirror post 510, and pendulum electrode 530 each include electrically conductive materials that are electrically connected together such that mirror 502 and pendulum electrode 530 are maintained at a common electrical voltage also referred to herein as the pendulum voltage of the MEMS device 500. In some embodiments, hinge 520 includes an electrically conductive material that is electrically connected to the mirror 502 and pendulum electrode 530 such that hinge 520 is maintained at the pendulum voltage.

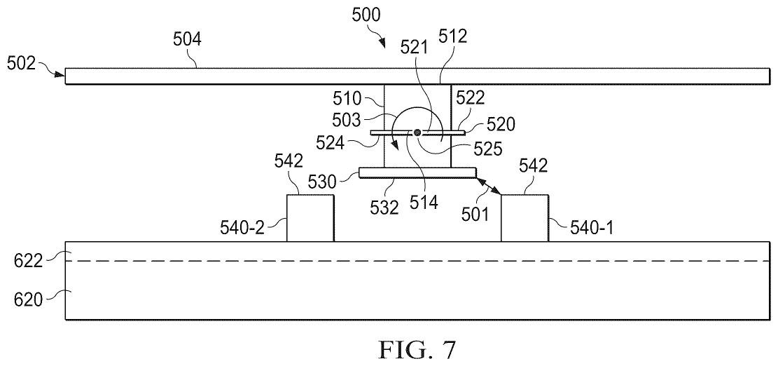

Mirror 502, mirror post 510, and pendulum electrode 530 are each rotatable in concert about the tilt axis 525 in each opposing angular direction. Pendulum electrode 530 is separated from each control electrode 540 by an air gap 501 (shown in FIG. 7) extending directly therebetween to permit relative rotation between pendulum electrode 530 (and the mirror 502 and mirror post 510 coupled thereto and the pair of control electrodes 540 about the tilt axis 525. Particularly, a rotational torque may be applied to the mirror 502 about tilt axis 525 via electrostatic forces transferred from control electrodes 540 to the pendulum electrode 530, as will be discussed further herein. In addition, rotational torque may be applied to the mirror 502 in the form of a mechanical biasing or restoring torque applied to the mirror 502 by the hinge 520 about tilt axis 525 in response to the mirror 502 rotating about the tilt axis 525 from a first or neutral angular position (shown in FIG. 6) to a second angular position angularly spaced about tilt axis 525 from the neutral angular position. The neutral angular position of mirror 502 corresponds to the angular position occupied by mirror 502 when the pendulum electrode 530 is not acted upon via electrostatic forces applied to the pendulum electrode 530 from the control electrodes 540. In other words, the neutral angular position of mirror 502 corresponds to the flat position of mirror 502.

As shown particularly in FIG. 6, the control electrodes 540 of MEMS device 500 define a control electrode layer 541 of MEMS device 500 while pendulum electrode 530 defines a pendulum electrode layer 531. Particularly, the control electrode layer 541 extends along the longitudinal axis 505 of MEMS device 500 towards pendulum electrode 530 and terminates at a control electrode plane 543 coincident with a terminal end 542 of each control electrode 540 when mirror 502 is in the neutral angular position. Similarly, pendulum electrode layer 531 extends along the longitudinal axis 505 of MEMS device 500 towards control electrodes 540 and terminates at a pendulum electrode plane 533 coincident with a terminal end 532 of pendulum electrode 530 when mirror 502 is in the neutral angular position.

In this exemplary embodiment, the neutral angular position of mirror 502 corresponds to a flat position of the mirror 502. Alternatively, the neutral angular position of mirror 502 may not correspond to the flat position of mirror 502 whereby the mirror 502 may extend, for example, at an acute angle relative to the longitudinal axis 505 of MEMS device 500. In this exemplary embodiment, hinge 520 defines the neutral angular position of mirror 502 in which hinge 520 is disposed in a neutral or unbiased state where hinge 520 does not apply a restoring torque to the mirror 502 about tilt axis 525.

Rotation of mirror 502 about tilt axis 525 departing from the neutral angular position in either angular direction may induce a mechanical strain in the hinge 520 resulting in the application by the hinge 520 of the restoring torque to mirror 502 in the angular direction of the neutral angular position thereof. Additionally, hinge 520 restricts rotation of mirror 502 relative to control electrodes 540 about rotational axes other than tilt axis 525. Alternatively, mirror 502 may be rotatable about a plurality of different rotational axes in other embodiments.

The restoring torque applied by hinge 520 to the mirror 502 of MEMS device 500 may be overcome through the application of a set of control voltages to the control electrodes 540 of MEMS device 500 whereby an electrostatic torque is applied to the mirror 502 through the pendulum electrode 530 via electrostatic forces applied between control electrodes 540 and pendulum electrode 530. The control voltages may be applied to control electrodes 540 via a power supply electrically connected to control electrodes 540 through, for example, a substrate of MEMS device 500.

As an illustrative example, FIG. 7 illustrates the application of a non-zero first control voltage to a first control electrode 540-1 of MEMS device 500 (where both the pendulum electrode 530 and a second control electrode 540-2 each maintained at zero voltage) whereby a voltage difference equaling the first control voltage is applied between the first control electrode 540-1 and the pendulum electrode 530. This voltage difference between the first control electrode 540-1 and pendulum electrode 530 results in the application of an electrostatic force to the pendulum electrode 530 that is translated into an electrostatic torque 503 applied to the mirror 502 through pendulum electrode 530 and about tilt axis 525.

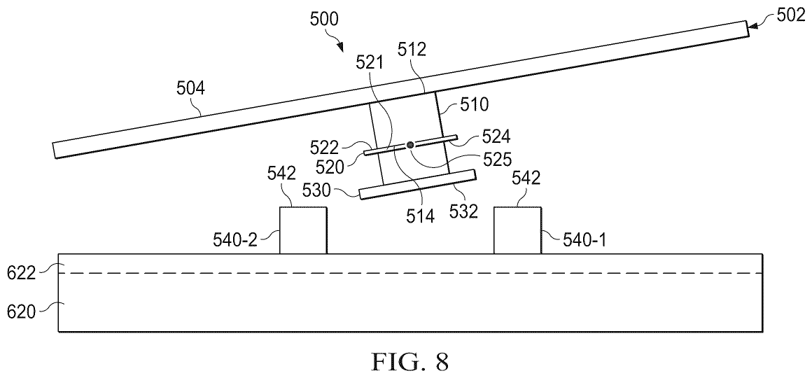

Electrostatic torque 503 overcomes the opposing restoring torque applied to mirror 502 from hinge 520 whereby mirror 502 is rotated in a first angular direction (illustrated as counterclockwise in FIG. 8) away from the neutral angular position. Mirror 502 continues to rotate in the first angular direction until the electrostatic torque 503 applied to mirror 502 in the first angular direction by first control electrode 540-1 is balanced or equalized by the opposing restoring torque applied to mirror 502 from hinge 520 whereby the rotation of mirror 502 is arrested and maintained at a second angular position (shown in FIG. 8) that is angularly spaced from the neutral angular position. Mirror 502 may be maintained in the second angular position until the control voltages applied to pendulum electrode 530 by control electrodes 540 (e.g., the first control voltage applied by first control electrode 540-1) is altered thereby altering the magnitude or angular direction of the electrostatic torque 503 applied to mirror 502 through pendulum electrode 530.

By modulating the set of control voltages applied to the control electrodes 540 of MEMS device 500, mirror 502 may be rotated between an opposing pair of maximum or delimiting angular positions (e.g., 40 degrees apart in some embodiments, 60 degrees apart in some embodiments, 120 degrees apart in some embodiments as but a few examples) each angularly spaced from the neutral angular position of mirror 502. For example, the delimiting angular positions of mirror 502 may correspond to the maximum tilt angle of mirror 502 in some embodiments. Additionally, mirror 502 remains entirely spaced from each of the control electrodes 540 when occupying either of the delimiting positions such that mirror 502 remains free of physical contact of each of the control electrodes 540 irrespective of the angular position currently occupied by mirror 502. In other words, mirror 502 remains free of physical contact with each of the control electrodes 540 when occupying a maximum tilt angle thereof, thereby avoiding issues of stiction resulting from said physical contact which could otherwise interfere with the performance of MEMS device 500.

As shown particularly in FIG. 6, mirror 502 is spaced by a first distance 507 (e.g., extending along longitudinal axis 505) from the control electrode plane 543 when the mirror 502 is in the neutral or flat position. Additionally, pendulum electrode plane 533 (defined by the position of the pendulum electrode 530 along longitudinal axis 505 in this exemplary embodiment) is spaced by a second distance 509 (e.g., along longitudinal axis 505) from the control electrode plane 543 when mirror is in the neutral or flat position. A ratio of the first distance to the second distance may influence the operation of the MEMS device 500. For example, for a given set of control voltages, increasing the ratio may correspondingly increase the magnitude of electrostatic forces applied by control electrodes 540-1 and 540-2 to the pendulum electrode 530 relative to the magnitude of electrostatic forces applied by control electrodes 540-1 and 540-2 to the mirror 502 itself. Conversely, reducing the ratio may act to undesirably reduce the difference in magnitude in electrostatic forces imparted to the mirror 502 and pendulum electrode 530. In other words, increasing the ratio gradually reduces the magnitude of electrostatic forces imparted to the mirror 502 (for a given set of control voltages) towards zero. However, too great a ratio between the first distance 507 and the second distance 509 may not be practical for at least some applications due to size or other design requirements for the MEMS device 500. In some embodiments, the ratio of the first distance 507 to the second distance 509 is between 2:1 and 10:1.

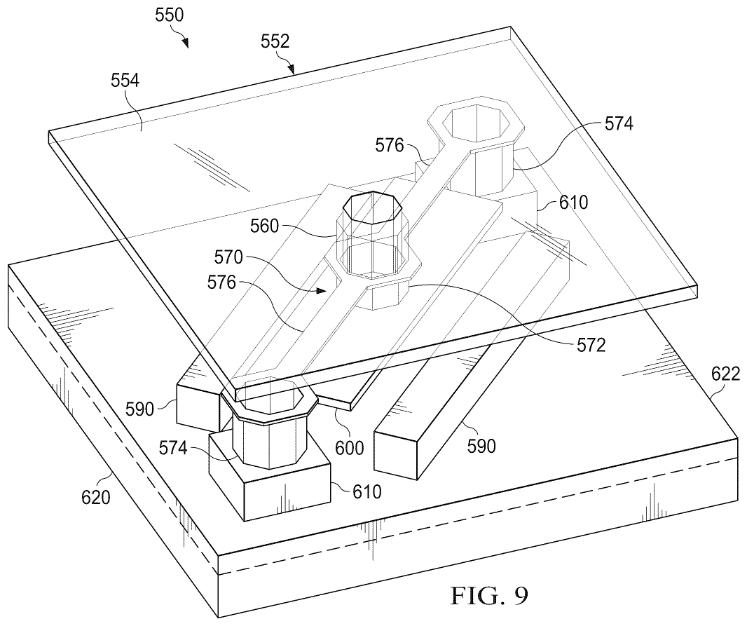

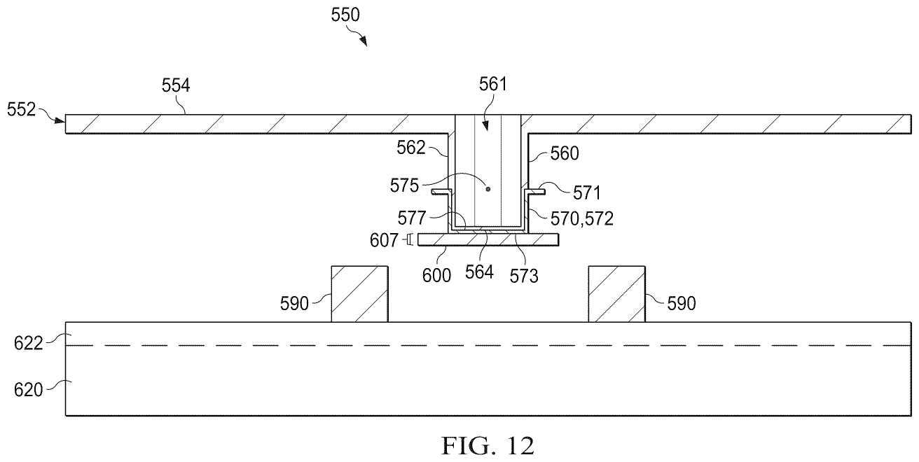

FIGS. 9-12 illustrate schematically another MEMS device 550 in accordance with principles disclosed herein. MEMS device 550 includes a pixel (e.g., a DMD pixel) and thus may also be referred to herein as pixel 550. In this exemplary embodiment, MEMS device 550 generally includes a mirror 552, a mirror post 560, a hinge 570, a pair of control or address electrodes 590, a pendulum electrode 600, a pair of bias electrodes 610, and a semiconductor (e.g., silicon) substrate 620 including an upper oxide layer and a memory cell 622 that includes or contains data corresponding to the voltages applied by control electrodes 590 and/or bias electrodes 610. In this exemplary embodiment, control electrodes 590 and pendulum electrode 600 are each elongate in shape which may help stabilize or isolate the rotation of mirror 552 about a tilt axis 575 (shown in FIG. 12) thereof in some applications.

The mirror 552 of MEMS device 550 has a reflective surface 554 such as, for example, polished aluminum. Mirror 552 is shown as rectangular or diamond-shaped in FIGS. 9-12; however, the shape of mirror 552 may vary from that shown in FIGS. 9-12 in other embodiments. As shown particularly in FIG. 12, the mirror post 560 (which may comprise a via) of MEMS device 550 physically couples mirror 552 with hinge 570 and has a first end 562 coupled to the mirror 552, and a second end 564 coupled to hinge 570. Additionally, hinge 570 has a first side 571 and a second side 573. In this exemplary embodiment, the first side 571 of hinge 570 is coupled to the second end 564 of mirror post 560. In addition, hinge 570 has or defines the tilt axis 575 that extends through the hinge 570. As shown particularly in FIG. 12, mirror post 560 has a central opening 561 that extends to a terminal end thereof formed by the second end 564 of mirror post 560. Particularly, the second end 564 of mirror post 560 is seated against a base 577 of hinge 570 at least partially defining the second side 573 thereof.

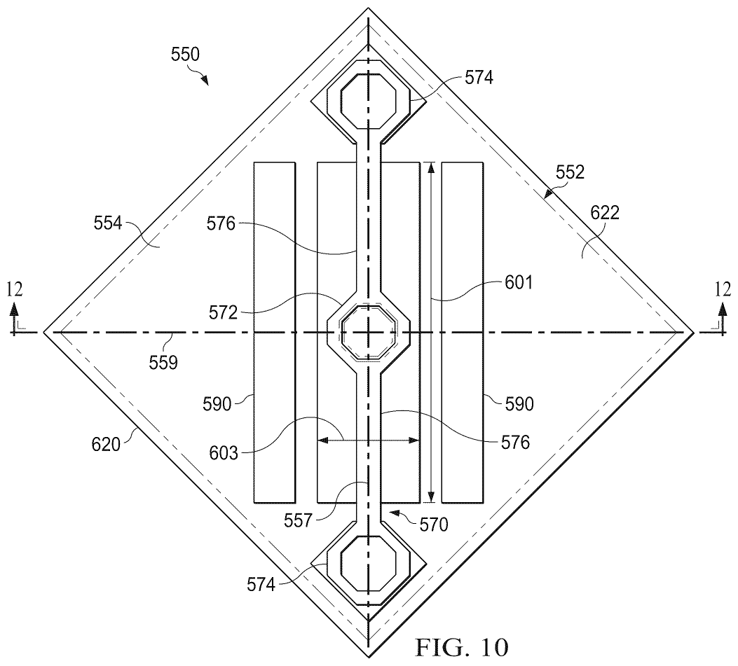

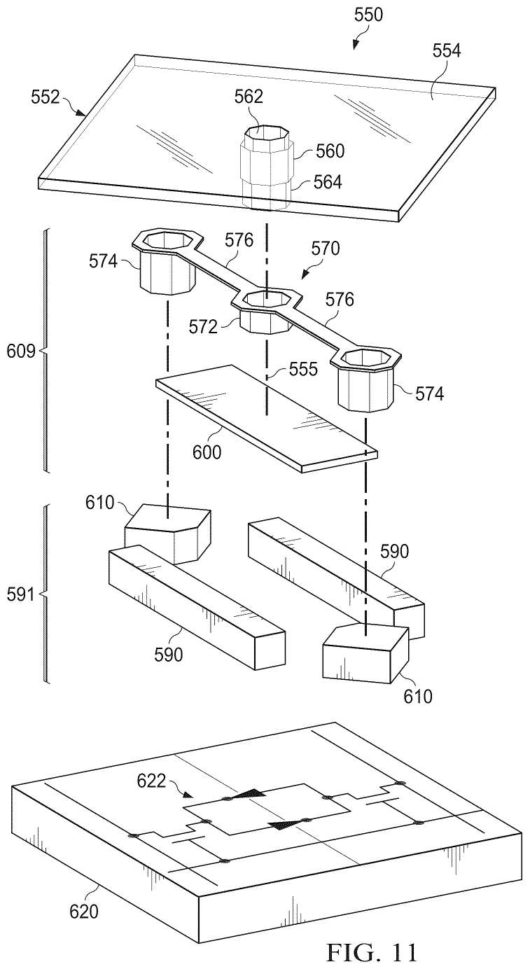

In this exemplary embodiment, hinge 570 generally includes a central hinge post 572, a pair of outer or laterally spaced outer hinge posts 574, and a pair of torsion arms 576 mechanically connecting the central hinge post 572 of hinge 570 with the outer hinge posts 574 thereof. Particularly, in this exemplary embodiment, outer hinge posts 574 and bias electrodes 610 of MEMS device 550 are spaced along a first lateral axis 557 (shown in FIG. 10) extending orthogonal a longitudinal axis 555 (shown in FIG. 11) of MEMS device 550. Additionally, in this exemplary embodiment, control electrodes 590 are spaced along a second lateral axis 559 (shown in FIG. 10) extending orthogonal both longitudinal axis 555 and the first lateral axis 557. Alternatively, control electrodes 590 and/or bias electrodes 610 may be positioned in other orientations (e.g., not along lateral axes 557 and/or 559) in other embodiments.

Central hinge post 572 and outer hinge posts 574 are each generally tubular extending longitudinally (e.g., parallel longitudinal axis 555) in this exemplary embodiment, with the second end 564 of mirror post 560 received in an internal opening or receptacle of the central hinge post 572. Alternatively, central hinge post 572 and/or outer hinge posts 574 may be shaped or configured differently in other embodiments. For example, central hinge post 572 and/or outer hinge posts 574 may not be tubular in some embodiments. Additionally, in this exemplary embodiment, outer hinge posts 574 are positioned on or extend from the bias electrodes 610 of MEMS device 550. With outer hinge posts 574 supported on bias electrodes 610, central hinge post 572 restricts rotation of mirror 552 relative to substrate 620 about the tilt axis 575.

Pendulum electrode 600 is coupled to the second side 573 of hinge 570. In this exemplary embodiment, pendulum electrode 600 is positioned centrally along longitudinal axis 555 and is physically coupled and electrically connected to the second side 573 of the central hinge post 572 of hinge 570. Additionally, in this exemplary embodiment, pendulum electrode 600 includes a rectangular plate having a longitudinal length 601 extending along the first lateral axis 557 when mirror 552 is in the flat position, a lateral width 603 (shown in FIG. 10 extending along the second lateral axis 559 when mirror 552 is in a flat position, and a thickness 607 (shown in FIG. 12) extending along the longitudinal axis 555 of MEMS device 550. In this exemplary embodiment, control electrodes 590 are similarly elongate in shape where each control electrode 590 is spaced laterally along second lateral axis 559 from the longitudinal axis 555 of MEMS device 550. In addition, in this exemplary embodiment, each control electrode 590 has the same or similar longitudinal length as the longitudinal length 601 of pendulum electrode 600. Alternatively, the shape or configuration of control electrodes 590 and/or pendulum electrode 600 may vary in other embodiments. For example, in other embodiments, control electrodes 590 and/or pendulum electrode 600 may not have a square or rectangular cross-sectional area and instead may be curved and/or include more or fewer than four separate sides.

In this exemplary embodiment, both hinge 570 and pendulum electrode 600 include electrically conductive materials electrically connected together whereby hinge 570 and pendulum electrode 600 are maintained at a common electrical voltage also referred to herein as the pendulum voltage of MEMS device 550. In addition, bias electrodes 610 are electrically connected to the hinge 570 and pendulum electrode 600 whereby the pendulum voltage may be controlled through the operation of bias electrodes 610. For example, bias electrodes 610 may be electrically connected to a power supply through, for example, the substrate 620 of MEMS device 550. In some embodiments, mirror 552 and mirror post 560 also include electrically conductive materials electrically connected to the hinge 570 and pendulum electrode 600 whereby the mirror 552 is also maintained at the pendulum voltage.

As shown particularly in FIG. 11, the control electrodes 590 and bias electrodes 610 of MEMS device 550 define a first electrode layer 591 of MEMS device 500 while pendulum electrode 530 defines a second or pendulum electrode layer 609 that is spaced along longitudinal axis 555 from the first electrode layer 591. Additionally, in this exemplary embodiment, mirror 552 of MEMS device 550 includes a neutral angular position which corresponds to a flat position of the mirror 552 where the longitudinal axis of mirror 552 is concentric with the longitudinal axis 555 of MEMS device 550. Alternatively, the neutral angular position of mirror 552 may not correspond to the flat position of mirror 552 whereby the mirror 552 may extend, for example, at an acute angle relative to the longitudinal axis 555 of MEMS device 550.

Rotation of mirror 552 about tilt axis 575 departing from the neutral angular position in either angular direction induces mechanical strain in the torsion arms 576 of hinge 570 resulting in the application by the hinge 570 of the restoring torque to mirror 552 in the angular direction of the neutral angular position thereof. The restoring torque applied by hinge 570 to the mirror 552 may be overcome through the application of a set of control voltages to control electrodes 590 and/or bias voltages applied to bias electrodes 610 of MEMS device 550 whereby an electrostatic torque is applied to the mirror 552 through the pendulum electrode 600 via electrostatic forces applied between control electrodes 590 and pendulum electrode 600. The control voltages and/or bias voltages may be applied to control electrodes 590 and bias electrodes 610, respectively, via a power supply electrically connected to control electrodes 590 and bias electrodes 610 through the memory cell 622 of semiconductor substrate 620.

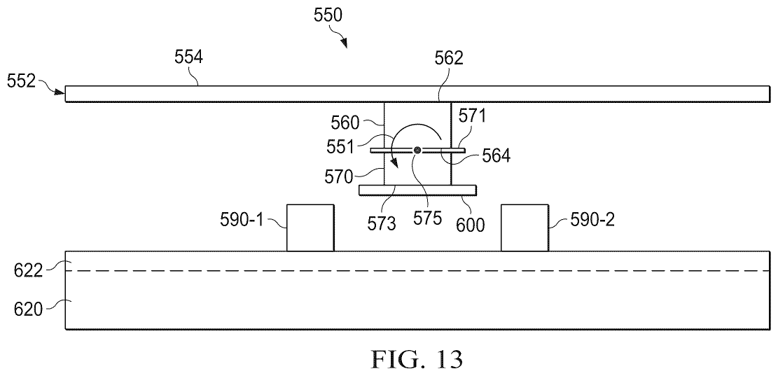

As an illustrative example, FIG. 13 illustrates the application of a non-zero first control voltage (e.g., equal to approximately 1.8 volts (V) as an example) to a first control electrode 590-1 of MEMS device 550 in conjunction with the application of a non-zero bias voltage (e.g., equal to approximately 20V as an example) applied to the pendulum electrode 600 through the bias electrodes 610 of MEMS device 550 whereby the pendulum voltage is equalized with or corresponds to the bias voltage applied to bias electrodes 610. Thus, the voltage difference between the first control voltage and the pendulum voltage, in this exemplary embodiment, does not equal the first control voltage but instead corresponds to the difference between the bias voltage (corresponding to the pendulum voltage) and the first control voltage applied to first control electrode 590-1. This voltage difference between the first control voltage applied to first control electrode 590-1 (second control electrode 590-2 maintained at zero voltage in this example) and the bias voltage applied to pendulum electrode 600 results in the application of an electrostatic force to the pendulum electrode 600 that is translated into an electrostatic torque 551 applied to the mirror 552 through pendulum electrode 600 and about tilt axis 575.

In some embodiments, the bias voltage allows for greater voltage differences given that bias voltages applied to mirror 552 may be greater than the control voltages which can, in some instances, be limited by static random-access memory (SRAM) transistor limits. Additionally, although bias voltages generally bias the mirror 552 towards the activated control electrode 590, negative bias voltages (e.g., −10V as an example) may be applied to mirror 552 to bias the mirror 552 instead away from a given activated control electrode 590.

Electrostatic torque 551 overcomes the opposing restoring torque applied to mirror 552 from hinge 570 whereby mirror 552 is rotated in a first angular direction (illustrated as counterclockwise in FIG. 13) away from the neutral angular position. The electrostatic torque 551 may result from an attractive electrostatic force between the second control electrode 590-2 and the pendulum electrode 600. Particularly, pendulum electrode 600 is pulled laterally by the electrostatic force applied by control electrode 590-2, rotating pendulum electrode toward control electrode 590-2 given that control electrode 590-2 is positioned below the hinge 570. The motion of pendulum electrode 600 rotates mirror 552 away from control electrode 590-2, preventing pull-in collapse of the mirror 552.

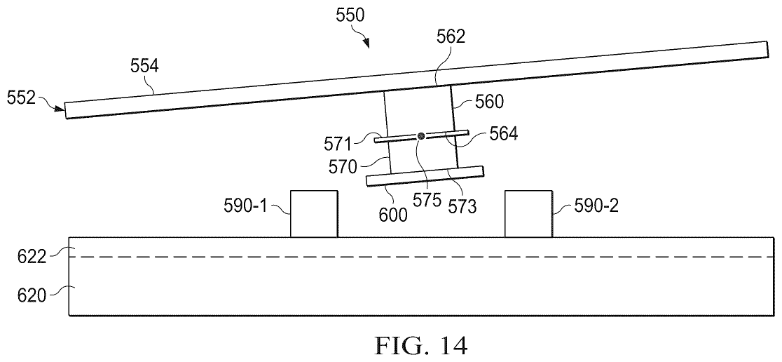

As an example, in some embodiments, both the first control voltage and the bias voltage may each be positive whereby the greatest voltage difference between pendulum electrode 600 and the pair of control electrodes 590 is between the second control electrode 590-2 and pendulum electrode 600 rather than the voltage difference between the first control electrode 590-1 and the pendulum electrode 600. In addition, FIG. 14 illustrates an example in which the first control voltage applied to first control electrode 590-1 is increased (e.g., to approximately 10V as an example) relative to the first control voltage applied to first control electrode 590-1 in FIG. 13. This increase in first control voltage results in a concomitant decrease in the voltage difference between first control electrode 590-1 and pendulum electrode 600, thereby resulting in continued rotation of mirror 552 in the first angular direction from the angular position of mirror 552 shown in FIG. 13.

By modulating the set of control voltages applied to the control electrodes 590 and the bias voltage applied to bias electrodes 610, mirror 552 may be rotated between an opposing pair of delimiting angular positions (corresponding to a maximum tilt angle of mirror 552) each angularly spaced from the neutral angular position of mirror 552. In this manner, the tilt angle of mirror 552 may be tuned via the control voltage level where the tilt angle of mirror 552 is controlled by the balance of electrostatic forces from control electrodes 590 and a restoring force applied by hinge 570. Additionally, mirror 552 remains entirely spaced from each of the control electrodes 590 and each of the bias electrodes 610 when occupying either of the delimiting positions such that mirror 552 remains free of physical contact of each of the control electrodes 590 and each of the bias electrodes 610 irrespective of the angular position currently occupied by mirror 552. In other words, mirror 552 remains free of physical contact with each of the control electrodes 590 and the bias electrodes 610 when occupying a maximum tilt angle thereof, thereby avoiding issues of stiction resulting from said physical contact which could otherwise interfere with the performance of MEMS device 550.

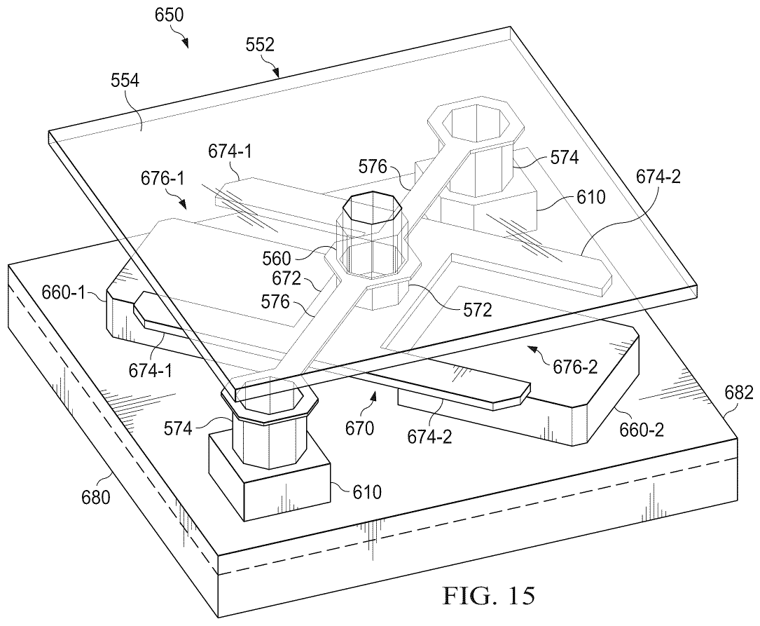

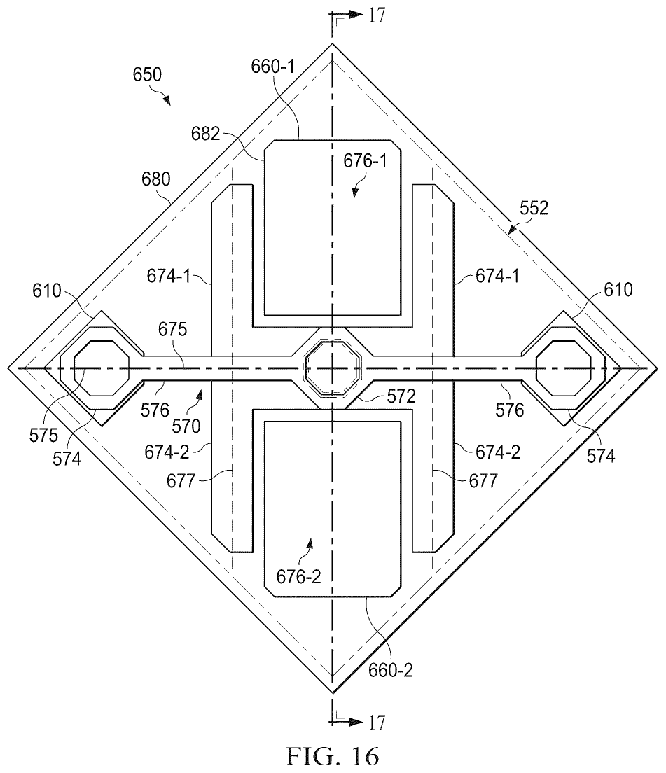

FIGS. 15-17 illustrate schematically another MEMS device 650 in accordance with principles disclosed herein. MEMS device 650 includes a pixel (e.g., a DMD pixel) and thus may also be referred to herein as pixel 650. MEMS device 650 includes some features in common with the MEMS device 550 shown in FIGS. 9-14, and shared features are labeled similarly. In this exemplary embodiment, MEMS device 650 generally includes mirror 552, mirror post 560, hinge 570, a pair of control or address electrodes 660 (shown as control electrodes 660-1 and 660-2 in FIGS. 15-17), a pendulum electrode 670, the pair of bias electrodes 610, and a semiconductor (e.g., silicon) substrate 680 including an upper oxide layer and a memory cell 682 that includes or contains data corresponding to the voltages applied by control electrodes 660 and/or bias electrodes 610.

The pendulum electrode 670 of MEMS device 650 is coupled to the second side 573 of hinge 570. In this exemplary embodiment, pendulum electrode 670 is positioned centrally along a longitudinal axis 655 of MEMS device 650 and is physically coupled and electrically connected to the second side 573 of the central hinge post 572 of hinge 570. Additionally, in this exemplary embodiment, pendulum electrode 670 includes a centrally positioned pendulum connector arm 672 and a plurality of pendulum fingers 674 (shown as pendulum fingers 674-1 and 674-2 in FIGS. 15-17) connected to pendulum connector arm 672 at terminal ends thereof.

The pendulum connector arm 672 of pendulum electrode 670 extends in a first lateral axis 675 and is coupled to the second side 573 of the central hinge post 572 of hinge 570. Additionally, pendulum fingers 674 extend along second lateral axes 677 each orthogonal to the first lateral axis 675. Particularly, a first pair of pendulum fingers 674-1 extend from opposing terminal ends of pendulum connector arm 672 in a first direction along the second lateral axes 677 while a second pair of pendulum fingers 674-2 extend from opposing terminal ends of pendulum connector arm 672 in an opposing second direction along second lateral axes 677. The pendulum fingers 674 of pendulum electrode 670 provide pendulum electrode 670 with a comb-shape with a pair of openings 676-1 and 676-2 formed between the corresponding pairs of pendulum fingers 674-1 and 674-2.

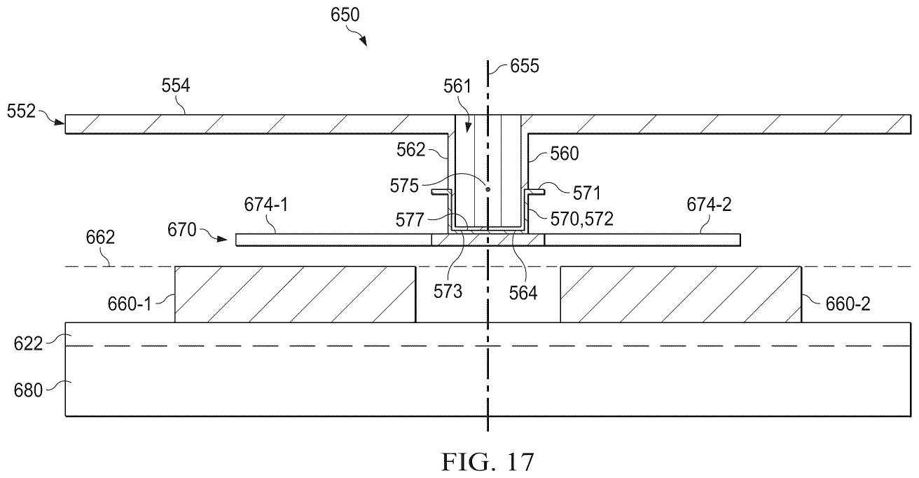

In this exemplary embodiment, the pair of control electrodes 660 are located in or entirely overlap openings 676-1 and 676-2 in a top view of MEMS device 650 such that each control electrode 660 is straddled or flanked by one of the pair of pendulum fingers 674-1 and 674-2. In this configuration, terminal ends or tips of the pendulum fingers 674-1 and 674-2 may overlap a control electrode plane 662 (shown in FIG. 17) defined by the pair of control electrodes 660 as pendulum electrode 670 rotates about tilt axis 575. Overlap between pendulum fingers 674-1 and 674-2 and control electrodes 660 may electrostatically define a pair of delimiting angular positions of the mirror 552 corresponding to a maximum tilt angle (in opposing angular directions about tilt axis 575) of the mirror 552.

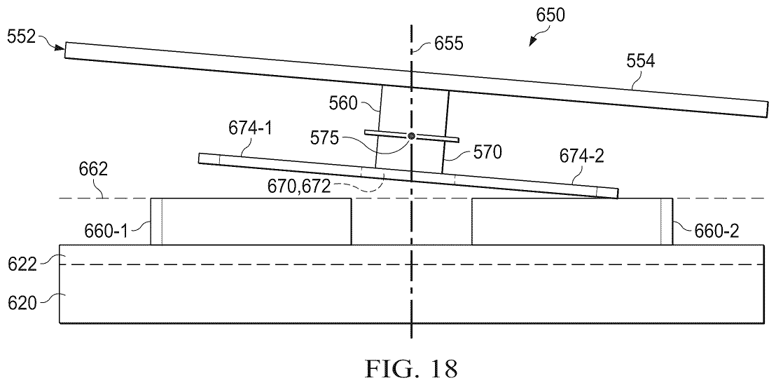

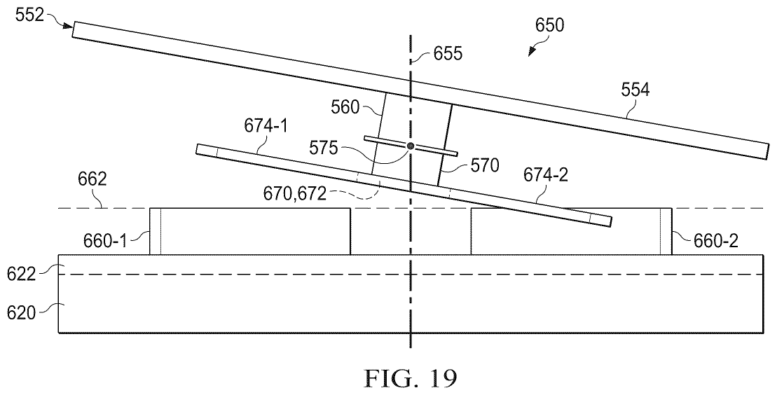

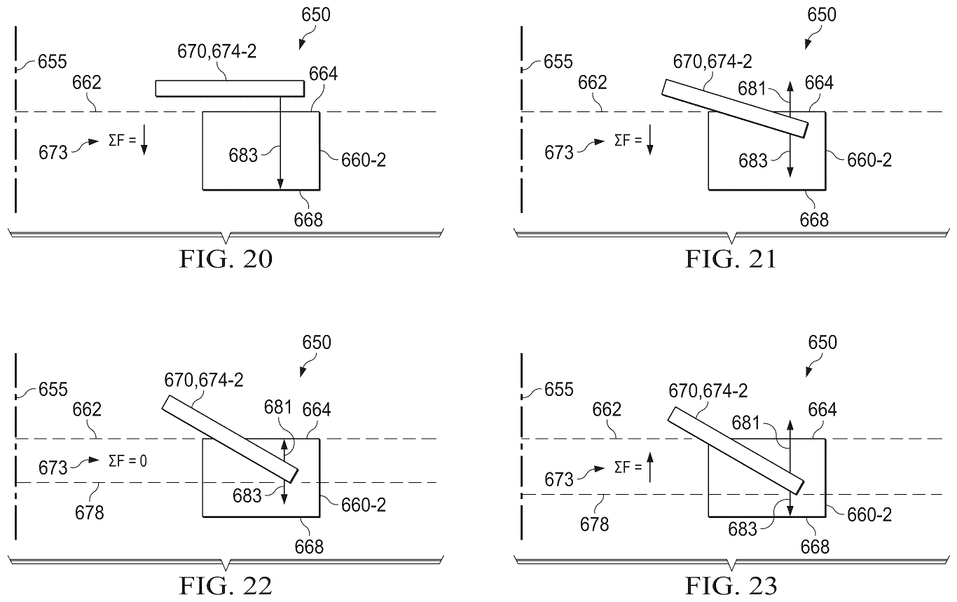

Referring to FIGS. 18-23, MEMS device 650 is shown schematically in FIGS. 20-23 (e.g., with substrate 680 hidden in FIGS. 20-23) in the interest of describing the overlap of pendulum fingers 674-1 and 674-2 with the pair of control electrodes 660 thereof. The comb design of pendulum electrode 670 permits pendulum fingers 674-1 and 674-2 to overlap with control electrodes 660 to achieve an equilibrium position to avoid pull-in collapse. Particularly, in this exemplary embodiment, the control electrode plane 662 is coincident with first or upper terminal ends 664 (shown in FIGS. 20-23 as will be discussed further herein) of the control electrodes 660 facing the pendulum electrode 670 and spaced from the substrate 680. In this example, FIGS. 18-23 illustrate the application of a control or address voltage to a second control electrode 660-2 (e.g., from approximately 1.8V to approximately 10V as an example) of MEMS device 650 whereby a resulting voltage differential between the second control electrode 660-2 and the pendulum electrode 670 apply a net electrostatic force 673 (shown in FIGS. 20-23) to the pendulum fingers 674-2 of pendulum electrode 670 and a resulting rotational torque to the mirror 552 about tilt axis 575 in a first rotational direction (clockwise in this example).

As shown particularly in FIGS. 20 and 21, in this example, the net electrostatic force 673 applied to pendulum fingers 674-2 is generally in a first (downwards in this example) direction along longitudinal axis 655 thereby driving the tips of pendulum fingers 674-2 generally in the downwards direction. This downwardly directed net electrostatic force 673 drives the tips of pendulum fingers 674-2 across the control electrode plane 662 whereby the pendulum fingers 674-2 overlap the control electrode plane 662 and the second control electrode 660-2 (e.g., in a side view of MEMS device 650) along longitudinal axis 655, as shown particularly in FIG. 21. In this manner, MEMS device 650 permits the pendulum electrode 670 to at least partially overlap the control electrode plane 662 when the mirror 552.

As pendulum fingers 674-2 continue to rotate about tilt axis 575 a first or upper portion of control electrodes 660 located (e.g., in a side view of MEMS device 650 along longitudinal axis 655) between the control electrode plane 662 and the tips of pendulum fingers 674-2 increases whereas a second or lower portion of control electrodes 660 located between a second or lower terminal end 668 of second control electrode 660-2 (opposite the upper terminal end 664 thereof) and the tips of pendulum fingers 674-2 decreases. Additionally, as the pendulum fingers 674-2 overlap control electrode plane 662, the net electrostatic force 673 applied to pendulum fingers 674-2 develops into two opposing components—a first or upwards component 681 extending generally in a second direction (upwards in this example) along longitudinal axis 655 and a second or downwards component 683 extending generally in the downwards direction along longitudinal axis 655. The net electrostatic force 673 applied to pendulum fingers 674-2 by second control electrode 660-2 corresponds to the sum of components 681 and 683 such that the direction of the resulting net electrostatic force 673 corresponds to the direction of the larger of the two components 681 and 683 of the net electrostatic force 673 applied to pendulum fingers 674-2 by second control electrode 660-2.

Additionally, in this example, the magnitudes of components 681 and 683 are contingent on or correlate with the magnitude or size (e.g., distance or length along longitudinal axis 655) of the upper and lower portions of second control electrode 660-2 described above. Particularly, as the size of the upper portion of second control electrode 660-2 increases and the size of the lower portion of second control electrode 660-2 correspondingly decreases in response to rotation of pendulum electrode 670 in the downwards direction, the magnitude of the upwards component 681 of net electrostatic force 673 increases as the magnitude of the downwards component 683 of net electrostatic force 673 correspondingly decreases. Conversely, as the size of the upper portion of second control electrode 660-2 decreases and the size of the lower portion of second control electrode 660-2 correspondingly increases in response to rotation of pendulum electrode 670 in an opposing second rotational direction about tilt axis 575 (counterclockwise in this example), the magnitude of the upwards component 681 of net electrostatic force 673 decreases as the magnitude of the downwards component 683 of net electrostatic force 673 correspondingly increases. Thus, with a fixed voltage differential between pendulum electrode 670 and second control electrode 660-2, the net electrostatic force 673 applied to pendulum electrode 670 (correlating with or proportional to the magnitude of rotational torque applied to mirror 552 about tilt axis 575) gradually declines as the pendulum fingers 674-2 continue to travel in the downwards direction along longitudinal axis 655 once crossing the control electrode plane 662.

The open comb design of pendulum electrode 670 allows for pendulum fingers 674-2 to exceed the terminal end 664 of control electrode 660-2 whereby the pendulum fingers 674-2 are be pulled down towards the activated control electrode 660-2. Particularly, as shown particularly in FIG. 22, in this example, upon the terminal ends of pendulum fingers 674-2 reaching an equilibrium point 678 along longitudinal axis 655, the net electrostatic force 673 reaches zero with upwards component 681 balancing or equaling in magnitude to the downwards component 683 of net electrostatic force 673. In some applications, angular momentum of mirror 552, mirror post 560, and pendulum electrode 670 may result in continued rotation of mirror 552 in the clockwise angular direction even if the voltage differential between mirror 552 and second control electrode 660-2 remains unchanged, as shown particularly in FIG. 23. Equilibrium point 678 corresponds to the position of pendulum electrode 670 at which components 681 and 683 are balanced, helping reduce the pull-in effect due to interference from mirror 552.

In this example, with the tips of pendulum fingers 674-2 exceeding the equilibrium point 678 (e.g., located along longitudinal axis 655 between the equilibrium point 678 and the lower terminal end 668 of second control electrode 660-2), the net electrostatic force 673 is applied to pendulum fingers 674-2 in the upwards direction urging the pendulum fingers 674-2 to return to the equilibrium point 678 corresponding to one of the pair of delimiting angular positions of the mirror 552. Thus, in some embodiments, by maintaining the voltage differential between pendulum electrode 670 and second control electrode 660-2, the mirror 552 may be (at least eventually) electrostatically locked into the corresponding delimiting angular position until the control voltage applied to second control electrode 660-2 is altered or the voltage differential between pendulum electrode 670 and the pair of control electrodes 660-1 and 660-2 is otherwise altered.

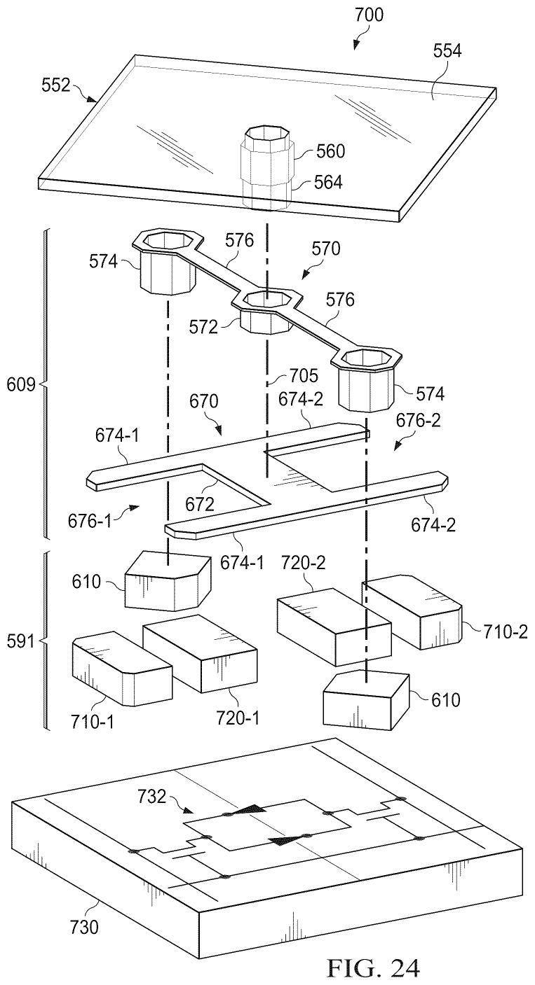

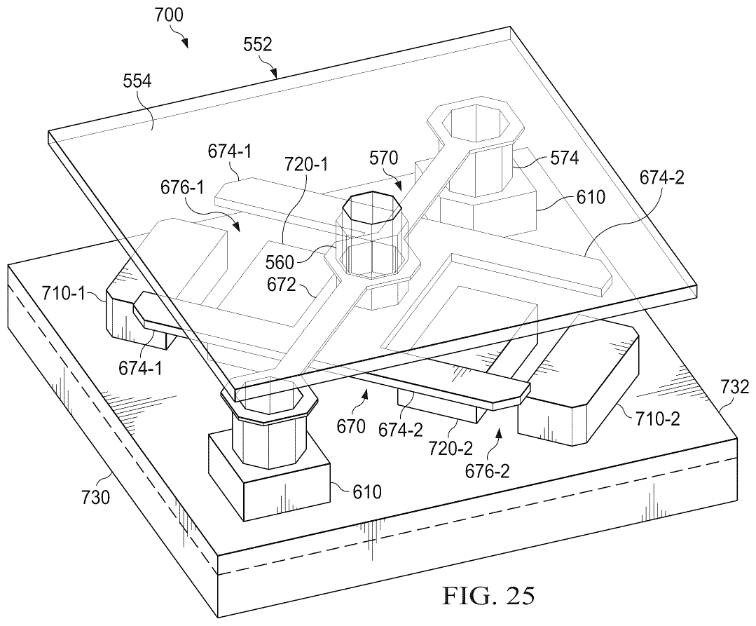

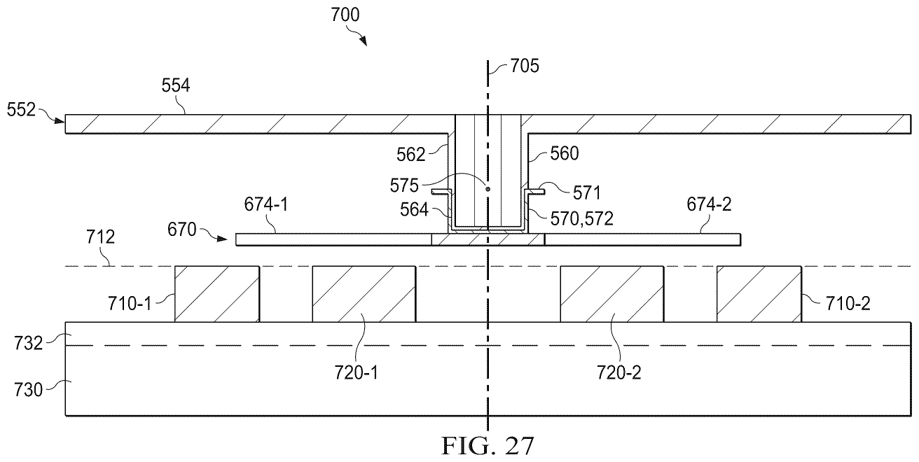

FIGS. 24-27 illustrate schematically another MEMS device 700 in accordance with principles disclosed herein. MEMS device 700 includes a pixel (e.g., a DMD pixel) and thus may also be referred to herein as pixel 700. MEMS device 700 includes some features in common with the MEMS device 650 shown in FIGS. 15-23, and shared features are labeled similarly. In this exemplary embodiment, MEMS device 700 has a longitudinal axis 705 and generally includes mirror 552, mirror post 560, hinge 570, pendulum electrode 670, a pair of control or address electrodes 710 (shown as control electrodes 710-1 and 710-2 in FIGS. 24-27), a pair of locking electrodes 720 (shown as locking electrodes 720-1 and 720-2 in FIGS. 24-27). and a semiconductor (e.g., silicon) substrate 730 including an upper oxide layer and a memory cell 732 that includes or contains data corresponding to the voltages applied by bias electrodes 610, control electrodes 710-1 and 710-2, and locking electrodes 720-1 and 720-2. Control electrodes 710-1/710-2 and locking electrodes 720-1/720-2 collectively define a control electrode plane 712. As will be discussed further herein, locking electrodes 720 may be addressed (e.g., via an electrical locking signal) separately from control electrodes 710 to selectably lock the position of the mirror 552 about the tilt axis 575.

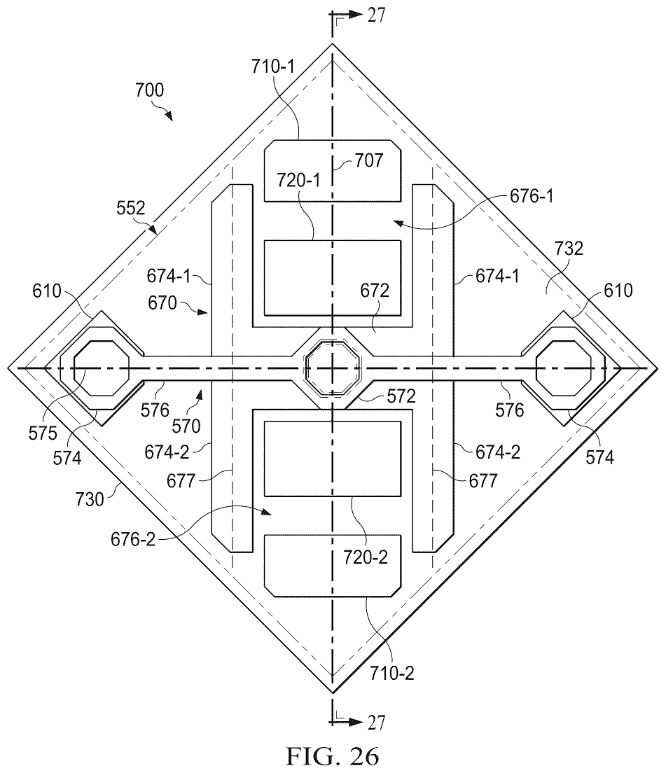

Control electrode 710-1 and locking electrode 720-1 are each at least partially positioned in or overlap (in a top view of MEMS device 700) opening 676-1 of pendulum electrode 670 while control electrode 710-2 and locking electrode 720-2 are each at least partially positioned in or overlap (in a top view of MEMS device 700) opening 676-2 of pendulum electrode 670. In this exemplary embodiment, control electrodes 710-1/710-2 and locking electrodes 720-1/720-2 are positioned and spaced along a lateral electrode axis 707 that is orthogonal tilt axis 575. Particularly, locking electrodes 720-1/720-2 are each positioned along lateral electrode axis 707 between the longitudinal axis 705 (which extends through lateral electrode axis 707 in this exemplary embodiment) and the corresponding pair of control electrodes 710-1/710-2, as shown particularly in FIG. 26.

In some embodiments, the pair of locking electrodes 720-1 and 720-2 are separately addressable (and independently addressable in certain embodiments) from the pair of bias electrodes 610 and control electrodes 710-1 and 710-2. In some embodiments, different control voltages may be applied to the pair of bias electrodes 610 (e.g., collectively applied to bias electrodes 610), the pair of locking electrodes 720-1 and 720-2 (e.g., collectively applied to locking electrodes 720-1 and 720-2), control electrode 710-1, and the control electrode 710-2 (e.g., different control voltages may be individually applied to control electrodes 710-1 and 710-2).

In some embodiments, different control voltages may be applied to the pair of bias electrodes 610 (e.g., collectively applied to bias electrodes 610), the locking electrode 720-1, the locking electrode 720-2 (e.g., different control voltages may be applied individually to locking electrodes 720-1 and 720-2), control electrode 710-1, and the control electrode 710-2 (e.g., different control voltages may be individually applied to control electrodes 710-1 and 710-2). The separate addressability and proximity of locking electrodes 720-1 and 720-2 to longitudinal axis 705 relative to control electrodes 710-1 and 710-2 may provide for greater tilt angles of mirror 552. Additionally, locking electrodes 720-1 and 720-2 may permit the mirror 552 to remain landed or positioned (e.g., about tilt axis 575) to the same side of the neutral angular position of mirror 552 following a change to at least one of the control voltages applied to control electrodes 710-1 and 710-2. Further, locking electrodes 720-1 and 720-2 permits the selection of waveforms for the control voltages applied to locking electrodes 720-1 and 720-2 that minimize transient or otherwise unintentional motion (e.g., rotation about tilt axis 575) of mirror 552 during operation of MEMS device 700.

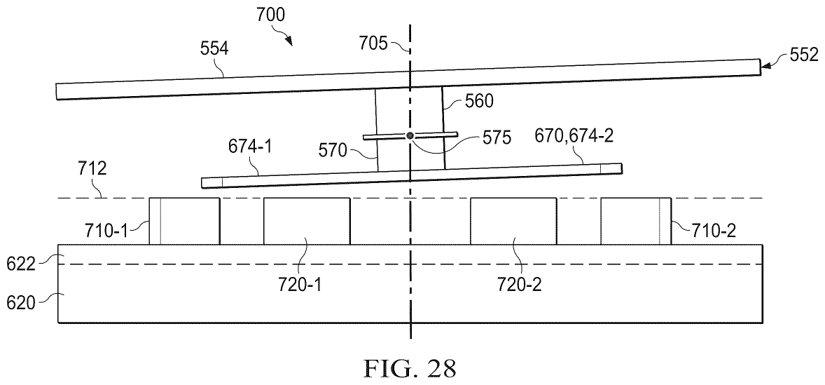

Referring to FIGS. 28-30, MEMS device 700 is shown schematically in the interest of describing the features of control electrodes 710-1/710-2 and locking electrodes 720-1/720-2. Particularly, in this example, FIG. 28 illustrates MEMS device 700 in a first state in which a first control voltage of 20 V is applied by bias electrodes 610 to the pendulum electrode 670, a second control voltage of 20V is also applied to each of the locking electrodes 720-1 and 720-2, a third control voltage of 0V is applied to control electrode 710-1, and a fourth control voltage of 1.8V is applied to control electrode 710-2. The application of the first through fourth control voltages to MEMS device 700 in the first state results in tilting of the mirror 552 by a first tilt angle in a first rotational direction (counterclockwise in this example) from a flat or neutral angular position of mirror 552.

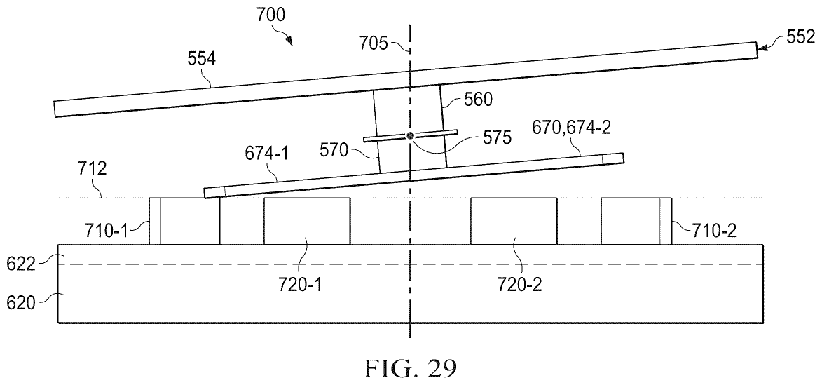

Additionally, FIG. 29 illustrates MEMS device 700 in a second state in which the fourth control voltage applied to control electrode 710-2 is increased from 1.8V to 10V with the first through third control voltages remaining the same as in the first state of MEMS device 700. In the second state of MEMS device 700, mirror 552 is rotated in the first rotational direction from the first tilt angle to a second tilt angle that is slightly greater than the first tilt angle.

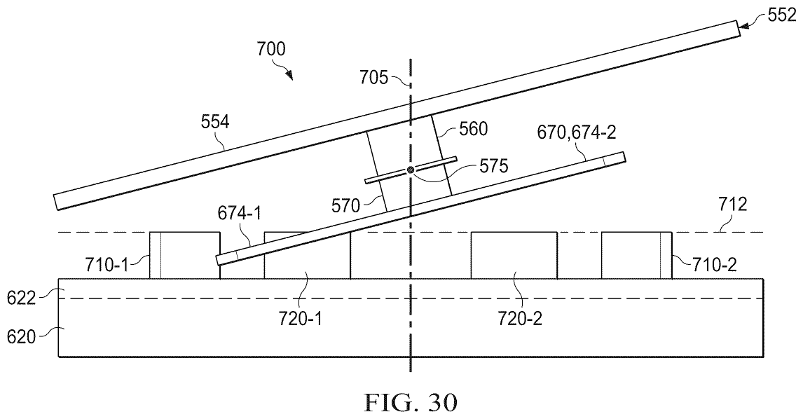

Further, FIG. 30 illustrates MEMS device 700 in a third state in which the second control voltage applied to each of locking electrodes 720-1 and 720-2 is reduced from 20V to −10V (resulting in a 30V differential between the pendulum electrode 670 and locking electrodes 720-1/720-2) while first, third, and fourth control voltages remain the same as in the second state of MEMS device 700 (e.g., control electrode 710-2 is maintained at 10V). In the third state of MEMS device 700, mirror 552 is rotated again in the first rotational direction from the second tilt angle to a third tilt angle that is greater than the second tilt angle. Thus, a tilt angle of mirror 552 may be maximized by controlling the control voltage applied to locking electrodes 720-1/720-2. Finally, the control voltages described above (e.g., the first through fourth control voltages) are only exemplary to facilitate the illustration and description of MEMS device 700.

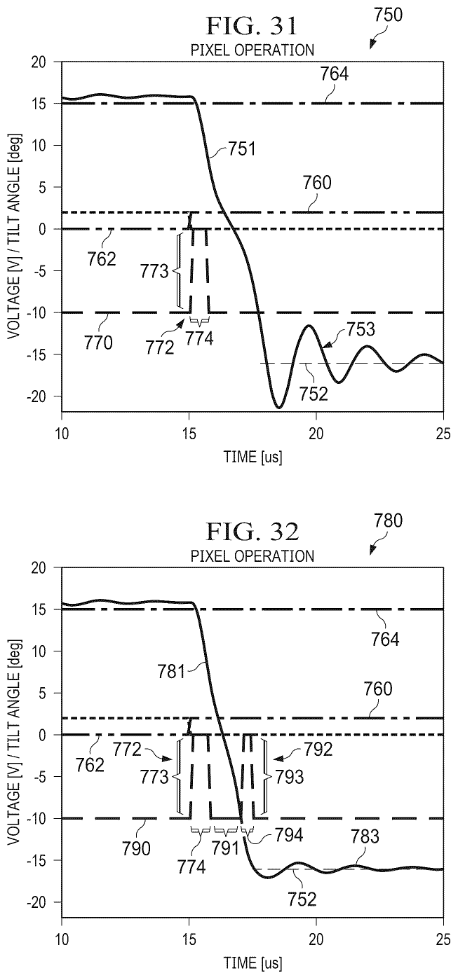

Referring to FIGS. 31 and 32, FIG. 31 illustrates a graph 750 of exemplary tilt position 751 (shown in units of degrees) of a mirror of a MEMS device (e.g., MEMS device 700 shown in FIGS. 24-30) over time (shown in units of microseconds) in conjunction with a first control voltage (each control voltage shown in units of V) 760 (e.g., corresponding to the control voltage applied to control electrode 710-1 of MEMS device 700), a second control voltage 762 (e.g., corresponding to the control voltage applied to control electrode 710-2 of MEMS device 700), a bias control voltage 764 (e.g., corresponding to the control voltage applied by bias electrodes 610), and a locking control voltage 770 (e.g., corresponding to the control voltage applied by locking electrodes 720-1 and 720-2).

In this example, the mirror of the MEMS device rotates from a first tilt angle (shown as approximately 16 degrees in FIG. 31) towards a desired second tilt angle (shown as approximately −16 degrees in FIG. 31) at a first point in time in response to the first control voltage 760 increasing from approximately 0V to approximately 2V at approximately the first point in time, the second control voltage 762 decreasing from approximately 2V to approximately 0V at approximately the first point in time, and the application of a first or actuation pulse 772 to the locking control voltage 770 at approximately the first point in time. In this example, the actuation pulse 772 of locking control voltage 770 is defined by a voltage amplitude 773 and a temporal duration 774. The voltage amplitude 773 may correspond to the difference between an initial voltage and a peak voltage of the actuation pulse 772 and which may be maintained for the substantial entirety or at least the majority of temporal duration 774. For example, actuation pulse 772 may include a step function in some embodiments.

While the actuation pulse 772 of locking control voltage 770 may assist in rapidly actuating or rotating the mirror from the first tilt angle towards the second tilt angle 752, the tilt position 751 of the mirror experiences substantial transient noise 753 before finally settling at the second tilt angle 752. Transient noise 753 may be defined by a maximum amplitude and a settling time or duration for the tilt angle 752 of the mirror following its transition to the second tilt angle (e.g., following the initial overshooting of the second tilt angle 752 by the mirror).

FIG. 32 illustrates another graph 780 of exemplary tilt position 781 (shown in units of degrees) of a mirror of a MEMS device (e.g., MEMS device 700 shown in FIGS. 24-30) over time (shown in units of microseconds) in conjunction with first control voltage 760, second control voltage 762, bias control voltage 764, and a locking control voltage 790 (e.g., corresponding to the control voltage applied by locking electrodes 720-1 and 720-2). Particularly, graph 780 is similar to graph 750 except that, in addition to actuation pulse 772, locking control voltage 770 includes a temporally spaced second or damping pulse 792 that temporally follows the actuation pulse 772. Particularly, the damping pulse 792 may follow the actuation pulse 772 following a non-zero delay or rest period 791 and may be defined by a voltage amplitude 793 and a temporal duration 794 that may be equal to or vary from the voltage amplitude 773 and temporal duration 774 of the actuation pulse 772.

In this example, damping pulse 792 assists in minimizing the amount of transient noise 783 in tilt position 781 following its transition from the first tilt angle to the second tilt angle 752. For example, damping pulse 792 may interfere with transient noise 783 to reduce an amplitude and/or a settling time thereof relative to the transient noise 753 shown in graph 750. In some embodiments, the extent of the non-zero delay 791 may correspond to the time required for the tilt position 781 to shift from the first tilt angle to the second tilt angle 752 such that the damping pulse 792 is initiated shortly before or at approximately the same time the tilt position 781 achieves (e.g., initially overshoots) the second tilt angle 752. Although graph 780 illustrates damping pulse 792 as an example of a control voltage waveform for damping the tilt position 781 of the mirror of a MEMS device, in other embodiments, waveforms other than the exemplary step function or damping pulse 792 shown in graph 780 may be used to assist in damping the tilt position 781.

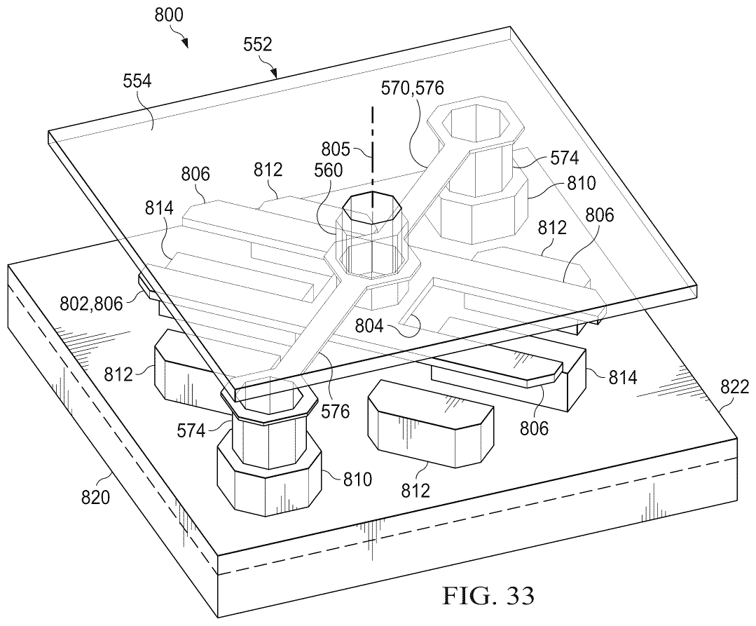

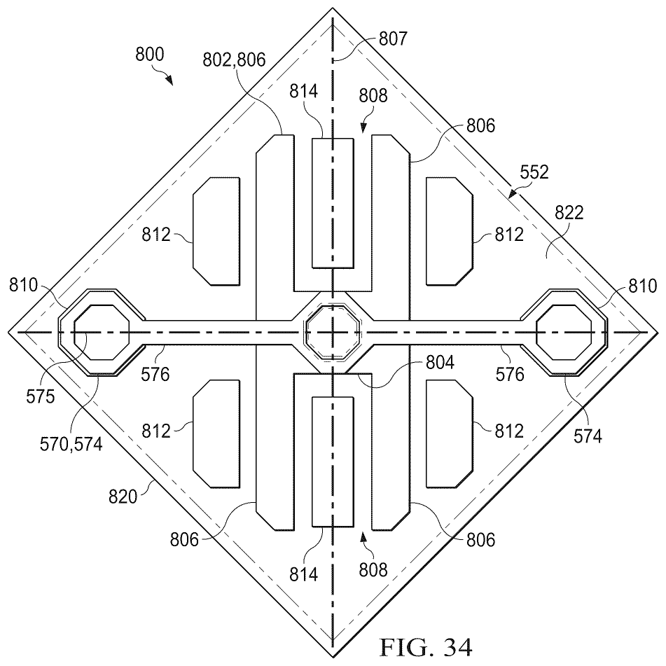

FIGS. 33 and 34 illustrate schematically another MEMS device 800 in accordance with principles disclosed herein. MEMS device 800 includes a pixel (e.g., a DMD pixel) and thus may also be referred to herein as pixel 800. MEMS device 800 includes some features in common with the MEMS device 700 shown in FIGS. 24-30, and shared features are labeled similarly. In this exemplary embodiment, MEMS device 800 has a longitudinal axis 805 and generally includes mirror 552, mirror post 560, hinge 570, a pendulum electrode 802, a pair of bias electrodes 810, two pairs of control or address electrodes 812, a pair of locking electrodes 814, and a semiconductor (e.g., silicon) substrate 820 including an upper oxide layer and a memory cell 822 that includes or contains data corresponding to the voltages applied by bias electrodes 810, control electrodes 812, and locking electrodes 814.

In this exemplary embodiment, each pair of control electrodes 812 flanks a corresponding pair of pendulum fingers 674 in a plan view of the MEMS device 800 with control electrodes 812 extending parallel pendulum fingers 674. Conversely, in this exemplary embodiment, each locking electrode 814 is flanked by a corresponding pair of pendulum fingers 674 in a plan view of MEMS device 800. In this configuration, pendulum fingers 674 are permitted to travel between locking electrodes 814 and their corresponding flanking control electrodes 812 via openings formed between each locking electrode 814 and its corresponding pair of flanking control electrodes 812.

In this exemplary embodiment, pendulum electrode 802 generally includes a centrally positioned pendulum connector arm 804 and a plurality of pendulum fingers 806 connected to pendulum connector arm 804 at terminal ends thereof. Additionally, locking electrodes 814 are positioned along a lateral axis 807 of MEMS device 800 that is orthogonal tilt axis 575 and intersects longitudinal axis 805. Locking electrodes 814 are each elongate extending along the longitudinal axis 805 and each are positioned in or overlap with (e.g., in a top view of MEMS device 800) openings 808 formed between corresponding pairs of pendulum fingers 806. However, in this exemplary embodiment, control electrodes 812 are each positioned in external openings 808 of pendulum electrode 802 such that each pair of pendulum fingers 806 is flanked (e.g., along a lateral axis extending parallel tilt axis 575) by a corresponding pair of the control electrodes 812.

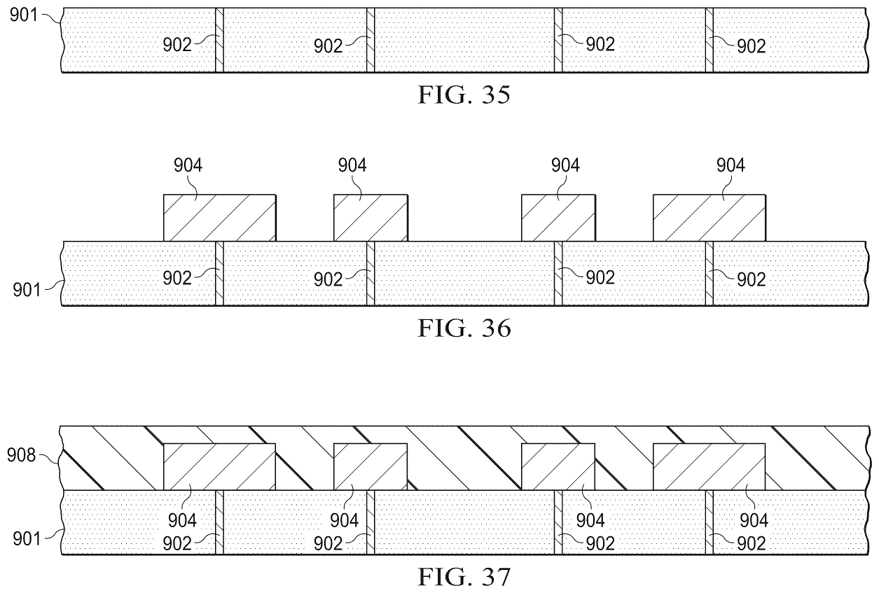

FIGS. 35-44 schematically illustrate a method or process for forming a MEMS device such as any of the embodiments of MEMS devices described herein (e.g., MEMS devices 500, 550, 650, 700, and 800). The method illustrated in FIGS. 35-44 is meant to only be exemplary, and the embodiments of MEMS devices disclosed herein may be formed using methods that vary from that shown in FIGS. 35-44. In this exemplary embodiment, a base or semiconductor (e.g., silicone) substrate 901 having an upper oxide layer and via connections 902 extending therethrough, as shown in FIG. 35. As shown in FIG. 36, a plurality of electrically conductive (e.g., metallic) control electrodes 904 (e.g., bias electrodes, control electrodes, and/or locking electrodes) are deposited and etched onto an upper surface or top of the completed substrate 901.

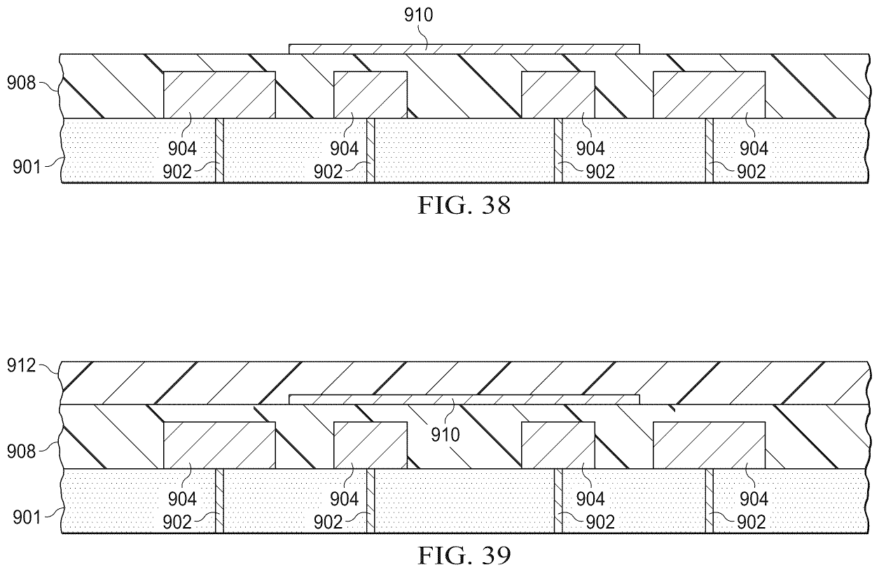

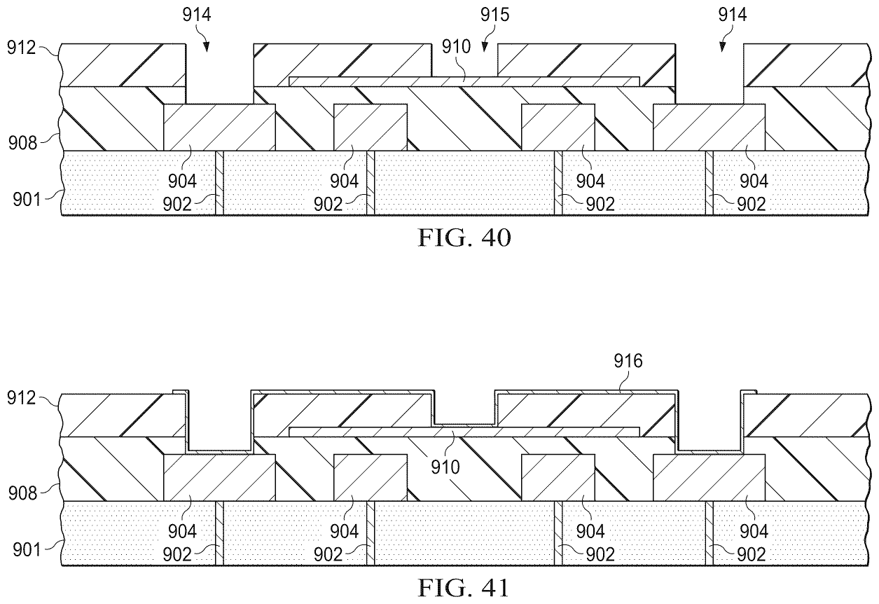

As shown in FIG. 37, a first or lower sacrificial spacer layer 908 is deposited and planarized atop the completed substrate 901 and the plurality of completed control electrodes 904 positioned thereon. An electrically conductive pendulum electrode 910 is then deposited and etched onto an upper surface or top of the completed lower sacrificial spacer layer 908, as shown in FIG. 38. As shown in FIG. 39, a second or intermediate sacrificial spacer layer 912 is deposited and planarized atop the completed lower sacrificial spacer layer 908, and the completed pendulum electrode 910 positioned thereon. As shown in FIG. 40, a plurality of openings 914 and 915 are then etched into the intermediate sacrificial spacer layer 912 and lower sacrificial spacer layer 908 at predefined locations therealong. Each opening 914 extends entirely through the intermediate sacrificial spacer layer 912 and partially into the lower sacrificial spacer layer 908 to an upper surface or top of a corresponding control electrode 904. Additionally, opening 915 extends through intermediate sacrificial spacer layer 912 to an upper surface or top of the pendulum electrode 910.

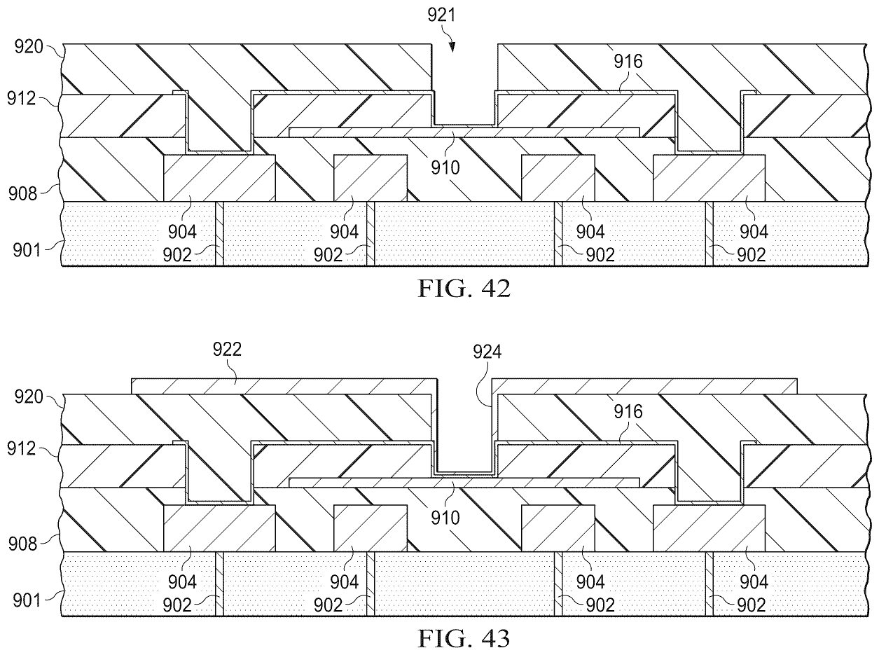

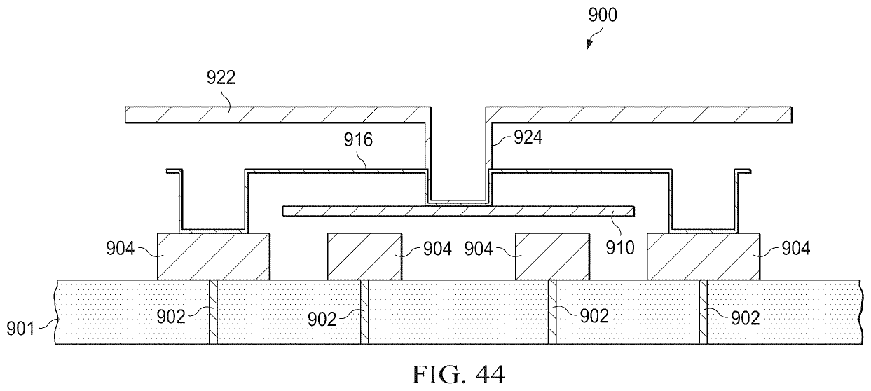

As shown in FIG. 41, an electrically conductive torsion hinge 916 is deposited and etched at least partially across the top of intermediate sacrificial spacer layer 912, including across the previously formed openings 914 and 915. Additionally, layer 912 may also define one or more vias and a mirror post. A third or upper sacrificial spacer layer 920 is deposited and planarized atop the completed intermediate sacrificial spacer layer 912 and the completed hinge 916, as shown in FIG. 42. Additionally, an opening 921 is etched into an upper surface or top of the upper sacrificial spacer layer 920, the opening 921 extending entirely to an upper surface or top of the hinge 916. As shown in FIG. 43, an electrically conductive mirror 922 and adjoining mirror post 924 are deposited and etched at least partially across an upper surface or top of upper sacrificial spacer layer 920, including across the previously formed opening 921 with mirror post 924 extending through the opening 921. Finally, as shown in FIG. 44, each of the sacrificial spacer layers 908, 912, and 920 may be removed to complete the formation of a MEMS device 900 including the substrate 901, control electrodes 904, pendulum electrode 910, hinge 916, mirror 922, and mirror post 924.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

A circuit or device that is described herein as including certain components may instead be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be coupled to at least some of the passive elements and/or the sources to form the described structure either at a time of manufacture or after a time of manufacture, for example, by an end-user and/or a third-party.

While certain components may be described herein as being of a particular process technology, these components may be exchanged for components of other process technologies. Circuits described herein are reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

Uses of the phrase “ground voltage potential” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter. Modifications are possible in the described examples, and other examples are possible within the scope of the claims.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device, or a semiconductor component. Furthermore, a voltage rail or more simply a “rail,” may also be referred to as a voltage terminal and may generally mean a common node or set of coupled nodes in a circuit at the same potential.

What is claimed is:

1. A microelectromechanical systems (MEMS) device comprising:
a mirror;
a mirror post having a first end and a second end, the first end coupled to the mirror;
a hinge having a first side and a second side, the first side of the hinge coupled to the second end of the mirror post;
a pendulum electrode coupled to the second side of the hinge; and
a pair of control electrodes spaced from the pendulum electrode.

2. The MEMS device of claim 1, wherein the pendulum electrode at least partially overlaps a control electrode plane of the pair of control electrodes when the mirror is in a first angular position.

3. The MEMS device of claim 1, wherein:
the mirror is spaced by a first distance from a control electrode plane of the pair of control electrodes when the mirror is in a neutral angular position;
a terminal end of the pendulum electrode is spaced by a second distance from the control electrode plane when the mirror is in the neutral angular position; and
a ratio of the first distance to the second distance is between 2:1 and 10:1.

4. The MEMS device of claim 1, further comprising:
a pair of hinge posts each coupled to the hinge, whereby the mirror post is positioned between the pair of hinge posts;
wherein the pair of control electrodes comprises a pair of address electrodes spaced from the pendulum electrode.

5. The MEMS device of claim 4, further comprising a substrate which supports the pair of hinge posts and the pair of control electrodes.

6. The MEMS device of claim 1, wherein the pendulum electrode comprises a pair of arms defining an opening therebetween configured for a first control electrode of the pair of control electrodes to pass therethrough as the mirror rotates about the tilt axis.

7. The MEMS device of claim 1, further comprising a pair of locking electrodes spaced from the pendulum electrode.

8. A microelectromechanical systems (MEMS) device, the MEMS device comprising:
a mirror;
a mirror post having a first end and a second end, the first end coupled to the mirror;
a hinge having a first side and a second side, the first side of the hinge coupled to the mirror post;
a pendulum electrode coupled to the second side of the hinge; and
a pair of control electrodes configured to selectably apply an electrostatic force between electrodes of the pair of control electrodes and the pendulum electrode to thereby rotate the mirror.

9. The MEMS device of claim 8, wherein the mirror has an opposing pair of delimiting angular positions, and wherein the mirror is spaced from the pair of control electrodes when occupying either of the delimiting angular positions.

10. The MEMS device of claim 8, wherein:
the mirror has an opposing pair of delimiting angular positions; and
at least one of the pair of delimiting angular positions defines an electrostatic equilibrium point of the pendulum electrode.

11. The MEMS device of claim 8, further comprising an address electrode electrically connected to the pendulum electrode.

12. The MEMS device of claim 8, wherein the hinge defines a tilt axis that extends through the hinge.

13. The MEMS device of claim 12, wherein the pair of control electrodes comprises a pair of locking electrodes configured to, in response to receiving a locking signal, lock the mirror about the tilt axis.

14. The MEMS device of claim 13, wherein the pair of locking electrodes are positioned between a pair of the address electrodes.

15. The MEMS device of claim 8, wherein:
the mirror is spaced by a first distance from a control electrode plane of the pair of control electrodes when the mirror is in a neutral angular position;
a terminal end of the pendulum electrode is spaced by a second distance from the control electrode plane when the mirror is in the neutral angular position; and
a ratio of the first distance to the second distance is between 2:1 and 10:1.

16. An optical system, comprising:
a light source configured to generate a light beam; and
a microelectromechanical systems (MEMS) device optically coupled to the light source, the MEMS device comprising:
a mirror configured to reflect the light beam;
a mirror post having a first end and a second end, the first end coupled to the mirror;
a hinge having a first side and a second side, the first side of the hinge coupled to the second end of the mirror post;
a pendulum electrode coupled to the second side of the hinge; and
a pair of control electrodes spaced from the pendulum electrode.

17. The optical system of claim 16, a controller electrically connected to the pair of control electrodes of the MEMS device, the controller configured to apply a set of control voltages to the pair of control electrodes.

18. The optical system of claim 17, wherein the controller is electrically connected to the mirror of the MEMS device.

19. The optical system of claim 17, wherein:
the pair of control electrodes comprises a pair of locking electrodes to lock the mirror about the tilt axis in an angular position in response to receiving a locking signal from the controller.

20. The optical system of claim 19, wherein the locking signal comprises a plurality of temporally spaced pulses of voltage applied to the pair of locking electrodes.
